(19) United States
(12) Patent Application Publication
(10) Pub. No.: US 2026/0005186 A1
(43) Pub. Date: Jan. 1, 2026

(54) SEMICONDUCTOR MANUFACTURING SYSTEM AND METHOD

(71) Applicant: Intel Corporation, Santa Clara, CA (US)

(72) Inventors: Yi LI, Chandler, AZ (US); Brandon MARIN, Gilbert, CA (US); Zhixin XIE, Chandler, AZ (US); Praveen SREERAMAGIRI, Gilbert, CA (US); Ibrahim EL KHATIB, Chandler, AZ (US); Robin McREE, Chandler, AZ (US); Jesse JONES, Chandler, AZ (US); Srinivas PIETAMBARAM, Chandler, AZ (US); Gang DUAN, Chandler, AZ (US); Manohar KONCHADY, Chandler, AZ (US)

(21) Appl. No.: 18/757,538

(22) Filed: Jun. 28, 2024

(51) Int. Cl. H01L 23/00; H01L 21/67; H01L 21/68; H01L 21/683

(52) U.S. Cl. CPC H01L 24/743; H01L 21/67259; H01L 21/681; H01L 21/6835; H01L 24/27; H01L 24/32; H01L 2224/27002; H01L 2224/27005; H01L 2224/2731; H01L 2224/27515; H01L 2224/32137; H01L 2224/743

(57) ABSTRACT

There may be provided a system that includes a workpiece-support assembly with a platform. The system may further include an alignment-detection assembly with an optical sensor oriented towards the platform. The system may further include a handling assembly with at least one manipulator positioned along at least a first movement plane that is substantially parallel with the platform or at least a second movement plane that is substantially perpendicular to the platform. The system may further include a bonding assembly with a dispenser positioned over the platform. The system may further include a fiducial-marking assembly with a drill oriented towards the platform. The system may further include a controller electrically connected to each of the optical sensor, the at least one manipulator, the dispenser, and the drill.

### BACKGROUND

In modern semiconductor manufacturing, precision and efficiency are paramount for meeting the demands of rapidly advancing technology. The assembly of semiconductor components, particularly delicate substrates like glass, requires meticulous alignment and handling to ensure optimal performance and reliability of a final product.

Traditionally, manual processes are the norm for substrate assembly, with operators relying on visual inspection and manual manipulation to align components. However, manual methods are prone to human error, leading to inconsistencies and inefficiencies in production. Moreover, manual handling can increase the risk of contamination and damage to sensitive components.

Recognizing these limitations, there is a need for an improved semiconductor manufacturing system and method that offers enhanced performance, reliability, and scalability.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. In the following description, various aspects are described with reference to the following drawings, in which:

FIG. 1A schematically depicts a system, according to various aspects;

FIG. 1B to FIG. 1D schematically depict an alignment-detection assembly and a handling assembly of the system of FIG. 1A, cooperating to align a first semiconductor workpiece within a central opening of a second semiconductor workpiece, according to various aspects;

FIG. 1E and FIG. 1F schematically depict a first variation of a bonding assembly of the system of FIG. 1A, according to various aspects;

FIG. 1G schematically depicts a second variation of the bonding assembly of the system of FIG. 1A, according to various aspects;

FIG. 1H schematically depicts the first semiconductor workpiece and the second semiconductor workpiece coupled via bonding material from the bonding assembly of FIG. 1G, according to various aspects;

FIG. 1I schematically depicts a fiducial-marking assembly of the system of FIG. 1A, according to various aspects;

FIG. 1J schematically depicts fiducials formed on the second semiconductor workpiece through the fiducial-marking assembly of FIG. 1I, according to various aspects;

FIG. 2A schematically depicts the first semiconductor workpiece, according to various aspects;

FIG. 2B is a cross-sectional view of the first semiconductor workpiece, taken along line A-A of FIG. 2A, according to various aspects;

FIG. 2C schematically depicts the first semiconductor workpiece and the second semiconductor workpiece assembled together, according to various aspects;

FIG. 2D is a cross-sectional view of the assembled first semiconductor workpiece and second semiconductor workpiece, taken along line AA-AA of FIG. 2C, according to various aspects;

FIG. 3A to FIG. 3F depict a process of bonding the first semiconductor workpiece and the second semiconductor workpiece via compression molding, according to various aspects;

FIG. 4A to FIG. 4F depict a process of bonding the first semiconductor workpiece and the second semiconductor workpiece using an adhesive, according to various aspects; and

FIG. 5 depicts a method, according to various aspects.

### DETAILED DESCRIPTION

Aspects described below in the context of the apparatus are analogously valid for the respective methods, and vice versa. Furthermore, it will be understood that the aspects described below may be combined, for example, a part of one aspect may be combined with a part of another aspect.

It should be understood that the terms “on”, “over”, “top”, “bottom”, “down”, “side”, “back”, “left”, “right”, “front”, “lateral”, “side”, “up”, “down” etc., when used in the following description are used for convenience and to aid understanding of relative positions or directions, and not intended to limit the orientation of any device, or structure or any part of any device or structure. In addition, the singular terms “a”, “an”, and “the” include plural references unless the context clearly indicates otherwise. Similarly, the word “or” is intended to include “and” unless the context clearly indicates otherwise.

The present disclosure generally relates to a system configured to assemble hybrid reconstitute panels (commonly referred to as “hybrid panels”). These hybrid panels are generally composed of two key components: a glass sub-panel (or a “first semiconductor workpiece”) and a robust organic Copper-Clad-Laminate (CCL) frame (or a “second semiconductor workpiece”). By combining the mechanical strength of the CCL frame with the unique properties of the glass sub-panel, hybrid panels offer enhanced durability and resilience, making them ideal for various semiconductor manufacturing applications.

At the heart of this disclosure is an automated system configured to perform precise alignment of the CCL frame relative to the glass sub-panel during an assembly process. By leveraging automation technologies, the system ensures optimal alignment and assembly accuracy, thereby enabling semiconductor manufacturers to consistently produce high-quality hybrid panels while streamlining production operations.

In various aspects, the system functions akin to a “linked tool”, capable of executing a series (or sequence) of automated tasks, such as glass sub-panel pick-and-place, CCL frame pick-and-place, bonding of glass sub-panel to CCL frame, fiducial formation, and/or trimming.

A notable advantage of the system is its capability to uphold positional accuracy of the semiconductor workpieces throughout the assembly process. By minimizing or eliminating human intervention while harmonizing various technologies, the system achieves high levels of precision and consistency, enhancing both product quality and production efficiency. In particular, the integration of various technologies serves to streamline the assembly process, optimizing productivity and throughput.

The system outlined in this disclosure, according to the various aspects, offers a significant advancement in the production of hybrid panels by enhancing efficiency, precision, and quality.

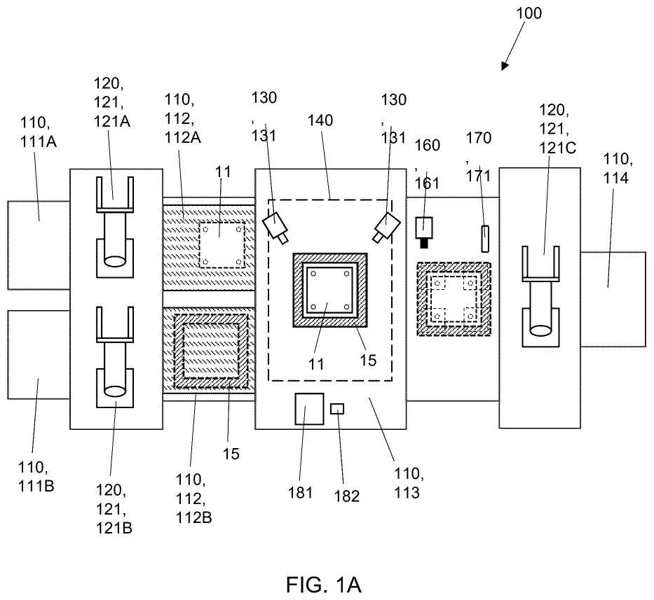

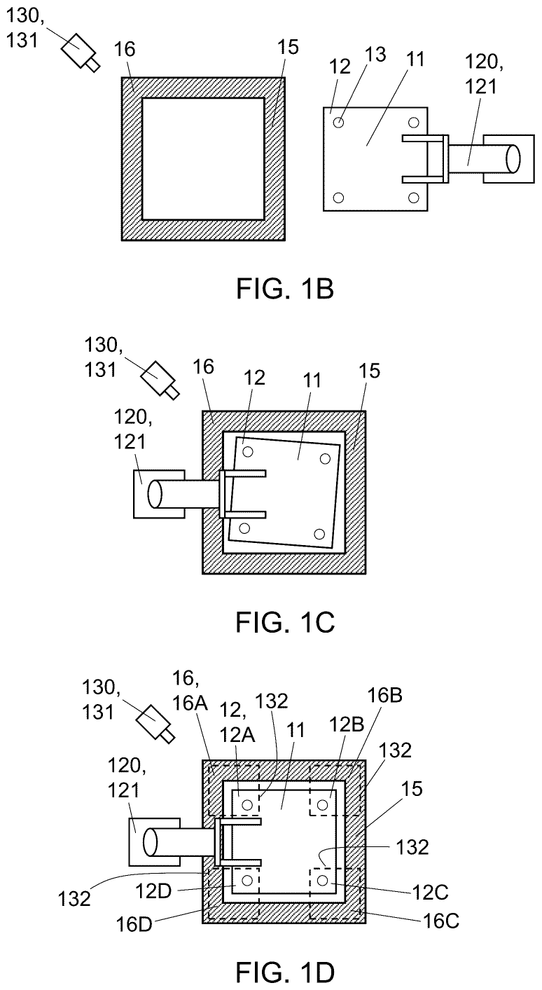

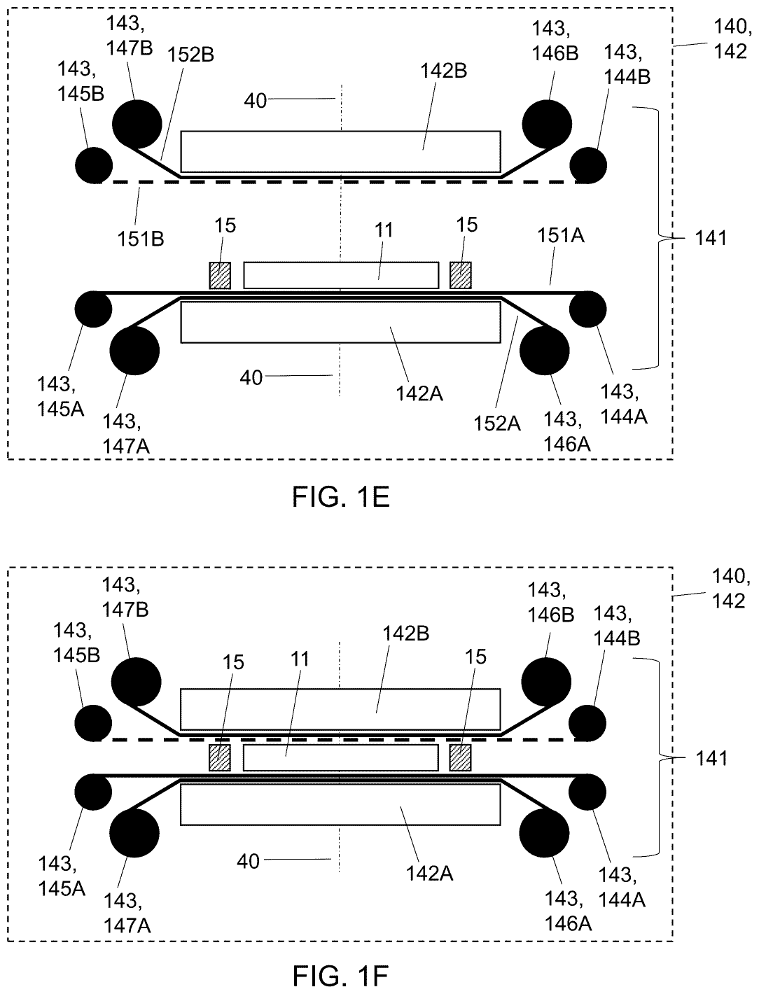

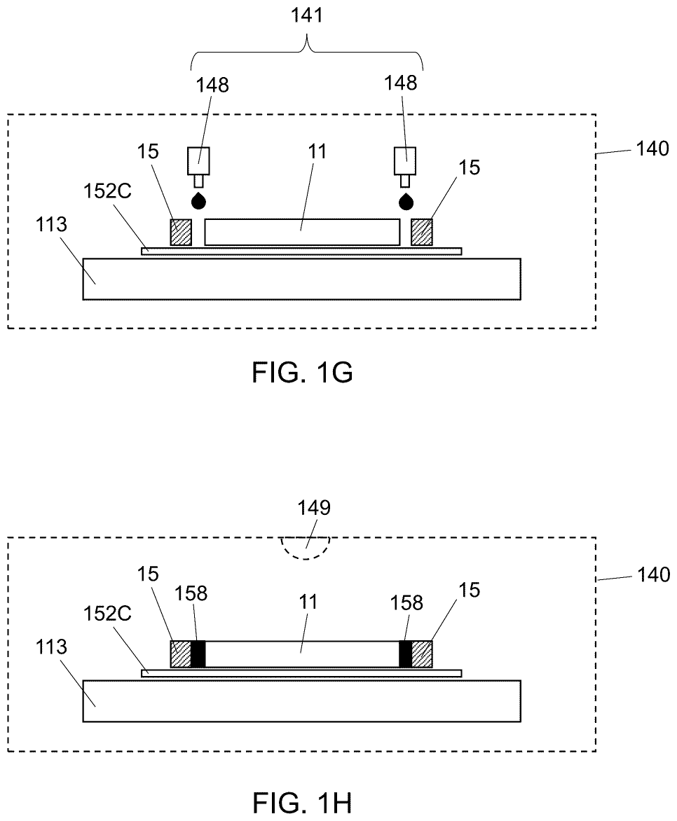

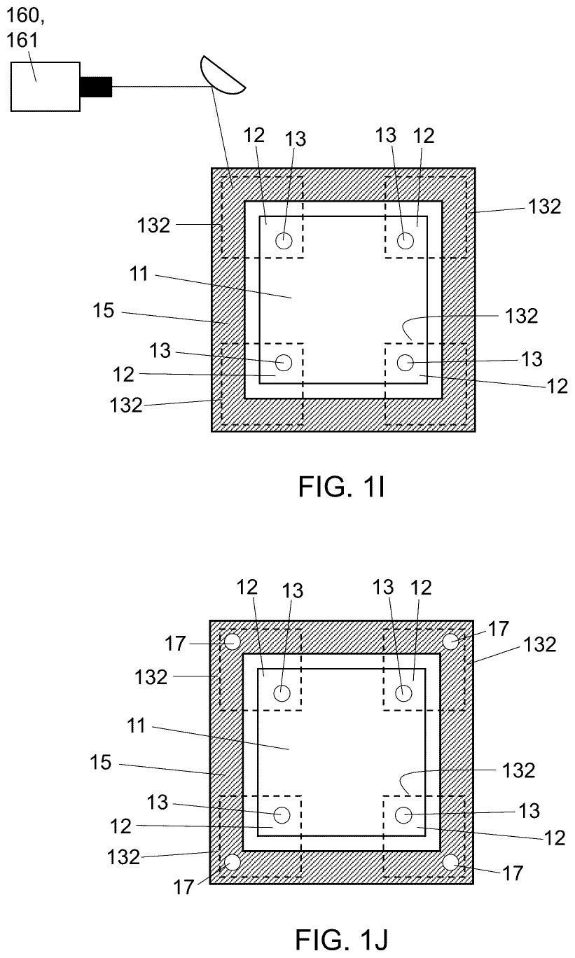

FIG. 1A schematically depicts a system, according to various aspects.

According to various aspects, with reference to FIG. 1A, there may be provided a system 100 (e.g. a manufacturing system or a product assembling system) configured to assemble a first semiconductor workpiece 11 and a second semiconductor workpiece 15 together, to form an assembled semiconductor workpiece. Herein, the assembled semiconductor workpiece may be referred to as a “hybrid panel”.

The first semiconductor workpiece 11 and the second semiconductor workpiece 15 may be distinct and/or discrete components of the hybrid panel. According to various aspects, the system 100 may be configured to receive the first semiconductor workpiece 11 and the second semiconductor workpiece 15 as separate pieces and, thereafter, assemble the first semiconductor workpiece 11 and the second semiconductor workpiece 15 together, in an automated manner, to fabricate the hybrid panel.

According to various aspects, as an example, the first semiconductor workpiece 11 may include or may be composed (e.g. composed entirely) of glass (e.g. aluminosilicate or aluminosilicate glass, borosilicate or borosilicate glass, alumino-borosilicate or alumino-borosilicate glass, silica or silica glass, or fused silica or fused silica glass, etc.). According to various aspects, the first semiconductor workpiece 11 may be or may include amorphous solid glass. According to various aspects, the first semiconductor workpiece 11 (e.g. glass) may include Silicon (Si) and/or Oxygen (O), as well as any one or more of Aluminium (Al), Boron (B), Magnesium (Mg), Calcium (Ca), Barium (Ba), Tin (Sn), Sodium (Na), Potassium (K), Strontium (Sr), Phosphorus (P), Zirconium (Zr), Lithium (Li), Titanium (Ti), and Zinc (Zn). According to various aspects, the first semiconductor workpiece 11 (e.g. glass) may include one or more additives, such as Aluminum oxide (Al₂O₃), Boron trioxide (B₂O₃), Magnesium oxide (MgO), Calcium oxide (CaO), Strontium oxide (SrO), Barium oxide (BaO), Tin (IV) oxide (Stannic oxide) (SnO₂), Sodium oxide (Na₂O), Potassium oxide (K₂O), Diphosphorus trioxide (P₂O₃), Zirconium dioxide (ZrO₂), Lithium oxide (LizO), Titanium (Ti), and/or Zinc (Zn). According to various aspects, as an example, the first semiconductor workpiece 11 (e.g. glass) may include or may compose at least 23% Silicon (Si) and at least 26% Oxygen (O) by weight and, furthermore, may include or compose at least 5% Aluminium (Al) by weight. As another example, the first semiconductor workpiece 11 (e.g. glass) may include or may compose at least 23% Silicon (Si) and at least 26% Oxygen (O) by weight and, furthermore, may include or compose at least 5% Aluminium (Al) by weigh as well as trace amount of Calcium oxide (CaO) and Magnesium oxide (MgO). According to various aspects, the first semiconductor workpiece 11 (e.g. glass) may include or may compose inorganic material. According to various aspects, the first semiconductor workpiece 11 (e.g. glass) may not include (in other words, may not compose) any organic material, such as organic adhesive.

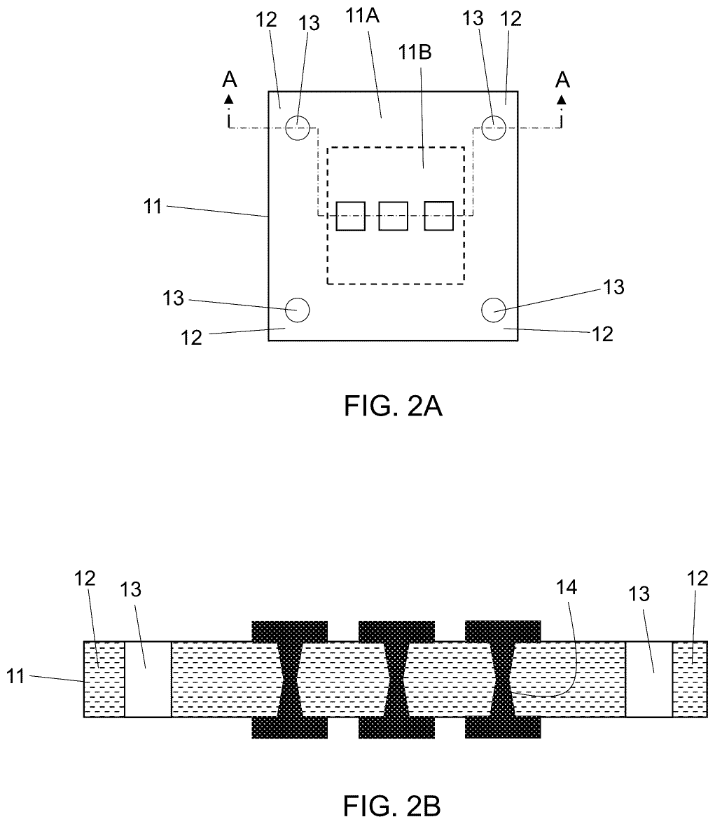

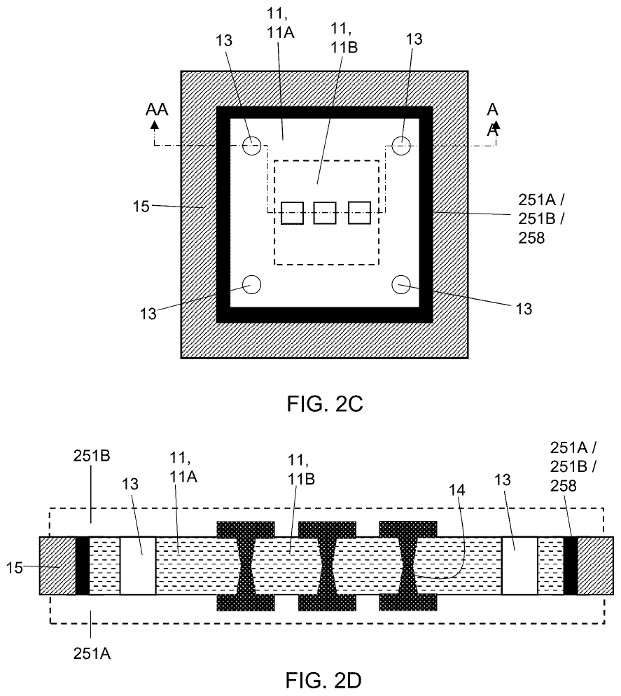

According to various aspects, the first semiconductor workpiece 11 may be provided in the form of a substrate (e.g. a glass substrate), a panel (e.g. a square or rectangular shaped panel), a layer (e.g. a glass layer), or a core (e.g. a glass core), etc. As an example, according to various aspects, the first semiconductor workpiece 11 (e.g. glass substrate, glass panel, glass layer, or glass core, etc.) may have a thickness ranging between approximately 50 μm to 1.4 mm (in other words, this range may include 50 μm and 1.4 mm). According to various aspects, the first semiconductor workpiece 11 (e.g. glass substrate, glass panel, glass layer, or glass core, etc.) may have a first width or length of between approximately 10 mm to approximately 520 mm and a second width or length (e.g. measured perpendicular to the first width) of between approximately 10 mm to approximately 520 mm. For example, the first width and/or the second width may be approximately 250 mm. According to various aspects, as an example, the first semiconductor workpiece 11 may be or may include a square (or squarish) or rectangle (or rectangular) prism volume with section(s) removed (e.g. via(s), through-hole via(s) which may be extending between bottom and upper surfaces of the first semiconductor workpiece 11, or blind via(s) which may be extending from the bottom surface or from the upper surface of the first semiconductor workpiece 11, etc.) and which may (e.g. may optionally be) filled with other material (e.g. metal). In other words, according to various aspects, as an example, the first semiconductor workpiece 11 may include at least one via which may include (or may be filled with) material, such as metal (see, for example, reference 14 of FIG. 2D, described later).

According to various aspects, the second semiconductor workpiece 15 may include or may be composed of a different material (or material composite) from the first semiconductor workpiece 11.

According to various aspects, the second semiconductor workpiece 15 may include or may be composed of at least a rigid or substantially rigid material (or material composite), such as a metal or metal alloy (e.g. copper or copper alloy), ceramic, rigid polymer, etc., or any other rigid or substantially rigid material (or material composite). According to various aspects, the second semiconductor workpiece 15 may include (e.g. optionally and/or further include) organic material. Specifically, according to various aspects, the second semiconductor workpiece 15 may include or may be (e.g. may be configured or function as) an organic Copper-Clad-Laminate (CCL) frame, which may serve as a protective frame around the first semiconductor workpiece 11.

In particular, according to various aspects, the second semiconductor workpiece 15 may be a protective frame that includes or defines a central opening (e.g. a through-hole opening), in other words, may include an opening at a central or core region of the second semiconductor workpiece 15, that is shaped and/or sized to accommodate the first semiconductor workpiece 11 therewithin. In particular, a size of the central opening of the protective frame (i.e. the second semiconductor workpiece 15) may be larger than a size of the first semiconductor workpiece 11. According to various aspects, the central opening of the second semiconductor workpiece 15 and the first semiconductor workpiece 11 may correspond in shape (e.g. may be similar or identical in shape) to each other. For instance, they may both be square-shaped or they may both be rectangular-shaped. Accordingly, according to various aspects, the second semiconductor workpiece 15 may be a square annular-shaped protective frame or a rectangular annular-shaped protective frame, while the first semiconductor workpiece 11 may be a square-shaped or rectangular-shaped panel or core. It is also envisaged that, in various other aspects (not shown), the first semiconductor workpiece 11 and the second semiconductor workpiece 15 may be of other shapes, such as a circular-shaped panel and a circular annular-shaped frame, respectively.

With reference to FIG. 1A, according to various aspects, the system 100 may include a workpiece-support assembly (or arrangement, module, or unit) 110 configured to accommodate (e.g. support) the first semiconductor workpiece 11 and the second semiconductor workpiece 15 thereon. Specifically, the workpiece-support assembly 110 may include a platform 113 configured to support or hold the first semiconductor workpiece 11 and the second semiconductor workpiece 15. According to various aspects, this platform 113 may either be stationary or movable (e.g. movable horizontally from one location to another location within the system 100, and/or movable vertically, capable of being raised or lowered within the system 100).

According to various aspects, the workpiece-support assembly 110 may further include a first workpiece-loading bay 111A (or port) configured (e.g. sized and/or shaped) to receive the first semiconductor workpiece 11, as well as include a second workpiece-loading bay 111B (or port) configured (e.g. sized and/or shaped) to receive the second semiconductor workpiece 15. As an example, according to various aspects, each of the first workpiece-loading bay 111A and the second workpiece-loading bay 111B may be an individual workpiece-loading bay that may be partitioned and/or spaced apart (in other words, distinct and/or separate) from the other workpiece-loading bay. Thus, the first semiconductor workpiece (e.g. an individual first semiconductor workpiece) 11 may be individually placed onto (or input into) the first workpiece-loading bay 111A, while the second semiconductor workpiece (e.g. an individual second semiconductor workpiece) 15 may be individually placed onto (or input into) the second workpiece-loading bay 111B. In other words, each semiconductor workpiece 11 and 15 may be placed onto its respective workpiece-loading bay 111A and 111B, separately.

Additionally, with reference to FIG. 1A, according to various aspects, the workpiece-support assembly 110 may further include a conveyor 112 extending between the platform 113 and each of the first workpiece-loading bay 111A and the second workpiece-loading bay 111B. According to various aspects, the conveyor 112 may be configured to convey (or transport or move) the first semiconductor workpiece 11 and the second semiconductor workpiece 15 to the platform 113 (e.g. after the first semiconductor workpiece 11 and the second semiconductor workpiece 15 are respectively placed onto the first workpiece-loading bay 111A and the second workpiece-loading bay 111B).

As an example, according to various aspects, the conveyor 112 may either include a single conveyor lane (e.g. a single belt conveyor) wide enough to accommodate both the first semiconductor workpiece 11 and the second semiconductor workpiece 15, or it may include a pair of distinct first and second conveyor lanes (e.g. belt conveyors) 112A and 112B (as depicted in FIG. 1A). According to various aspects, when the conveyor 112 includes a pair of distinct first and second conveyor lanes 112A and 112B, the first conveyor lane (e.g. a first belt conveyor) 112A may be controlled (e.g. operated) independently of the second conveyor lane (e.g. a second belt conveyor) 112B. This configuration may enable the first and second conveyor lanes 112A and 112B to operate (or transport semiconductor workpieces 11 and 15) at different speeds from one another. For instance, one conveyor lane may operate at a faster speed than the other, or one conveyor lane may be idle or stationary while the other is moving.

According to various aspects, a first end of the conveyor 112 (known as an “infeed end”) may be connected to and/or in communication with both the first workpiece-loading bay 111A and the second workpiece-loading bay 111B. Conversely, an opposite second end of the conveyor 112 (known as an “outfeed end”) may be connected to and/or in communication with the platform 113. For instance, the first end of the conveyor 112 may be positioned immediately adjacent or next to both the first workpiece-loading bay 111A and the second workpiece-loading bay 111B, while the second end of the conveyor 112 may be positioned immediately adjacent to the platform 113. Accordingly, when the first semiconductor workpiece 11 and the second semiconductor workpiece 15 are respectively placed onto the first workpiece-loading bay 111A and the second workpiece-loading bay 111B, they may transition to the first end of the conveyor 112 (e.g. by sliding along a surface, such as an inclined surface, of the workpiece-loading bay 111A and 111B, or by being transported by a handling assembly 120 of the system 100, described in detail later). The conveyor 112 may then convey the semiconductor workpiece 11 and 15 to the second end of the conveyor 112, where they may be transferred onto the platform 113 (i.e. situated immediately adjacent to the second end of the conveyor 112). According to various aspects, this transfer from the conveyor 112 to the platform 113 may be facilitated by movement of the conveyor 112 belt towards the platform 113.

It is also envisaged that, according to various other aspects (not shown), the workpiece-loading bays 111A and 111B may be directly connected to the platform 113 (e.g. without the need for an intermediary conveyor 112).

Referring to FIG. 1A, according to various aspects, the system 100 may include (e.g. further include) a handling assembly (or arrangement, module, or unit) 120 configured to be movable relative to the workpiece-support assembly 110. According to various aspects, this handling assembly 120 may be versatile in its movement capabilities, encompassing translational, rotational, diagonal, etc., movements relative to the workpiece-support assembly 110 or relative to any element (or portion or component) thereof.

According to various aspects, the handling assembly 120 may include at least one manipulator 121 (e.g. a pick and place tool or robot, a robotic arm, etc.) capable of handling (e.g. picking, releasing, and/or moving or transporting) any one or both of the first semiconductor workpiece 11 and the second semiconductor workpiece 15. According to various aspects, the at least one manipulator 121 may be movable relative to the workpiece-support assembly 110 (e.g. the platform 113). As an example, the at least one manipulator 121 may be positioned along a first movement plane that is substantially parallel with the workpiece-support assembly 110 (e.g. the platform 113), such that the at least one manipulator 121 may be movable in any direction substantially parallel to the workpiece-support assembly 110 (e.g. the platform 113). As another example, the at least one manipulator 121 may (e.g. additionally and/or alternatively) be positioned along a second movement plane that is substantially perpendicular to the workpiece-support assembly 110 (e.g. the platform 113), such that the at least one manipulator 121 may be movable in any direction substantially perpendicular to the workpiece-support assembly 110 (e.g. the platform 113). It is also envisaged that, in various other aspects, the at least one manipulator 121 may be movable diagonally, non-linearly, and/or in any other suitable manner, relative to the workpiece-support assembly 110 (e.g. the platform 113). Accordingly, the at least one manipulator 121 may be capable of moving the first semiconductor workpiece 11 and the second semiconductor workpiece 15 relative to each other as well as within (or around) the system 100 (e.g. from one location, portion, assembly, etc., of the system 100 to another location, portion, assembly, etc., of the system 100). As some examples, the at least one manipulator 121 may include any one or more (e.g. a combination of two or more) of the following: vacuum end effector(s) (e.g., vacuum cup(s) or vacuum gripper(s) for vacuum handling or gripping), mechanical end effector(s) or mechanical gripper(s), electrostatic end effector(s) or electrostatic gripper(s), etc., or any other type of end effector(s) or gripper(s). According to various aspects, as an example, the at least one manipulator 121 of the handling system 100 may be, or may form part of, an Equipment Front End Module (EFEM) of the system 100.

According to various aspects, the handling assembly 120 (or at least one manipulator 121 thereof) may be configured to aid in moving the first semiconductor workpiece 11 from the first workpiece-loading bay 111A to the conveyor 112 (or to the platform 113) as well as in moving the second semiconductor workpiece 15 from the second workpiece-loading bay 111B to the conveyor 112 (or to the platform 113). For instance, with reference to FIG. 1A, according to various aspects, the handling assembly 120 may include a first (e.g. distinct) manipulator 121A designated and/or configured to handle the first semiconductor workpiece 11 as well as a second (e.g. distinct) manipulator 121B designated and/or configured to handle the second semiconductor workpiece 15. According to various aspects, the first manipulator 121A may be controlled (e.g. operated) independently of the second manipulator 121B. In other words, according to various aspects, the first manipulator 121A may actuate or move independently of the second manipulator 121B. While FIG. 1A may depict the handling assembly 120 having at least the first manipulator 121A and the second manipulator 121B, it is also envisaged that, according to various other aspects, the handling assembly 120 may include any other number of manipulator(s) 121 (e.g. a single manipulator 121, or any other plural number of manipulators 121) configured for the same purpose.

According to various aspects, the system 100 may include (e.g. further include) an alignment-detection assembly (or arrangement, module, or unit) 130 configured to identify and/or detect the first semiconductor workpiece 11 and the second semiconductor workpiece 15 (e.g. when they are disposed on the workpiece-support assembly 110). In particular, the alignment-detection assembly 130 may be configured to detect a position of each of the first semiconductor workpiece 11 and the second semiconductor workpiece 15 disposed on the workpiece-support assembly 110 as well as identify and/or detect one or more features of each of the first semiconductor workpiece 11 and the second semiconductor workpiece 15 which may serve as alignment marker(s) (e.g. fiducial(s)), described in detail later.

According to various aspects, the alignment-detection assembly 130 may include a sensor 131. Specifically, the sensor 131 may be positioned over the workpiece-support assembly 110 (e.g. the platform 113) and/or oriented towards the workpiece-support assembly 110 (e.g. the platform 113). As some examples, this sensor 131 may include any one or a combination (e.g. at least two or more) of the following: camera(s), optical sensor(s), proximity sensor(s), laser distance sensor(s), ultrasonic sensor(s), etc. In particular, the sensor 131 of the alignment-detection assembly 130 may include or may form a vision system, which may (e.g. optionally and/or additionally) utilize image processing software, frame grabber(s), processing unit(s), etc., as well as a communication interface for communicating with any one or more other assemblies of the system 100.

According to various aspects, the handling assembly 120 may operate (e.g. move, and/or pick and place each of the first semiconductor workpiece 11 and the second semiconductor workpiece 15) based on the detection of the first semiconductor workpiece 11 and the second semiconductor workpiece 15 by the alignment-detection assembly 130. In other words, within the system 100, the alignment-detection assembly 130 and the handling assembly 120 may be configured to cooperate with each other to move the first semiconductor workpiece 11 and the second semiconductor workpiece 15 relative to each other and/or within (or around) the system 100 (e.g. in order to assemble them). According to various aspects, the alignment-detection assembly 130 and the handling assembly 120 may communicate via wired communication or via wireless communication. Furthermore, according to various aspects, the alignment-detection assembly 130 and the handling assembly 120 may communicate directly or via an intervening controller 181 which may be included in the system 100. Thus, for instance, according to various aspects, when the alignment-detection assembly 130 detects the first semiconductor workpiece 11 and the second semiconductor workpiece 15, data containing information on the detected first semiconductor workpiece 11 and second semiconductor workpiece 15 may be transmitted by the alignment-detection assembly 130 to the handling assembly 120 (e.g. directly from the alignment-detection assembly 130, or via the controller 181 of the system 100). Subsequently, the handling assembly 120 may operate (e.g. handle each of the first semiconductor workpiece 11 and the second semiconductor workpiece 15) based on this data received from the alignment-detection assembly 130.

As an illustration, according to various aspects, when the alignment-detection assembly 130 (e.g. its sensor 131) detects the first semiconductor workpiece 11 in the first workpiece-loading bay 111A and the second semiconductor workpiece 15 in the second workpiece-loading bay 111B, the alignment-detection assembly 130 may transmit data, or may cause a control signal to be transmitted by the controller 181, to the handling assembly 120 which prompts the handling assembly 120 to transport the first semiconductor workpiece 11 and the second semiconductor workpiece 15 from the first workpiece-loading bay 111A and the second workpiece-loading bay 111B to the conveyor 112 (i.e. which subsequently conveys the first semiconductor workpiece 11 and the second semiconductor workpiece 15 to the platform 113) or directly to the platform 113 itself (e.g. when the system 100 does not include the conveyor 112).

Furthermore, according to various aspects, when the first workpiece-loading bay 111A and the second workpiece-loading bay 111B (are) disposed on the workpiece-support assembly 110 (e.g. on the platform 113 thereof), the alignment-detection assembly 130 may be configured to detect at least one primary alignment marker 12 (see FIG. 1C and FIG. 1D) of the first semiconductor workpiece 11 and at least one primary alignment marker 16 (see FIG. 1C and FIG. 1D) of the second semiconductor workpiece 15. According to various aspects, a primary alignment marker 12 of the first semiconductor workpiece 11 may be a physical feature of the first semiconductor workpiece 11, such as a corner region (or a corner or edge corner, etc.) of the first semiconductor workpiece 11. Correspondingly, according to various aspects, a primary alignment marker 16 of the second semiconductor workpiece 15 may be a physical feature of the second semiconductor workpiece 15, such as a corner region (or a corner or edge corner, etc.) of the second semiconductor workpiece 15. In other words, the primary alignment markers 12 and 16 of both semiconductor workpieces 11 and 15 may be corresponding physical features (e.g. similar or identical in type, shape, area, section, portion, region, and/or position, etc., on, or of, the semiconductor workpieces 11 and 15). Hence, as another example, according to various other aspects, an edge or a side (e.g. extending between a pair of corners) of the first semiconductor workpiece 11 may serve as the primary alignment marker of the first semiconductor workpiece 11, while a corresponding or similar edge or side of the second semiconductor workpiece 15 may serve as the primary alignment marker of the first semiconductor workpiece 11.

According to various aspects, the alignment-detection assembly 130 (e.g. its sensor 131) may be configured (e.g. programmed or pre-programmed) to identify (e.g. automatically identify) a particular physical feature, such as a corner region, or an edge, or a side, etc., of each of the first semiconductor workpiece 11 and the second semiconductor workpiece 15 as the primary alignment marker of that semiconductor workpiece 11 or 15.

According to various aspects, the handling assembly 120 (e.g. its at least one manipulator 121) may be configured to be movable (e.g. to move the first semiconductor workpiece 11 and/or the second semiconductor workpiece 15) relative to the workpiece-support assembly 110 (e.g. the platform 113) based on the detection (i.e. by the alignment-detection assembly 130) of the primary alignment marker 12 of the first semiconductor workpiece 11 and the primary alignment marker 16 of the second semiconductor workpiece 15.

FIG. 1B to FIG. 1D schematically depict the alignment-detection assembly and the handling assembly of the system of FIG. 1A, cooperating to align the first semiconductor workpiece within the central opening of the second semiconductor workpiece, according to various aspects.

According to various aspects, with reference to FIG. 1B to FIG. 1D, based on the detection of the primary alignment marker 12 of the first semiconductor workpiece 11 and the primary alignment marker 16 of the second semiconductor workpiece 15 (i.e. by the alignment-detection assembly 130), the handling assembly 120 (or its at least one manipulator 121) may be configured to dispose the first semiconductor workpiece 11 within the central opening of the second semiconductor workpiece 15, with the primary alignment marker 12 of the first semiconductor workpiece 11 aligned with the primary alignment marker 16 of the second semiconductor workpiece 15. In other words, the first semiconductor workpiece 11 may be placed in the center (or substantially in the center) of the second semiconductor workpiece 15, with the primary alignment marker 12 of the first semiconductor workpiece 11 aligned with the primary alignment marker 16 of the second semiconductor workpiece 15.

As an example, with reference to FIG. 1C and FIG. 1D, alignment of the primary alignment marker 12 of the first semiconductor workpiece 11 and the primary alignment marker 16 of the second semiconductor workpiece 15 may be based on at least one “corner alignment” which may involve moving and/or rotating the first semiconductor workpiece 11 so that (or until) its primary alignment marker 12 (e.g. a corner region of the first semiconductor workpiece 11) is matched and/or aligned with the primary alignment marker 16 (e.g. a corresponding corner region) of the second semiconductor workpiece 15. According to various aspects, this alignment may involve the primary alignment markers 12 and 16 of both semiconductor workpieces 11 and 15 being immediately adjacent, proximal, or substantially coinciding, etc., with each other. According to various aspects, the system 100 may ensure that the first semiconductor workpiece 11 and the second semiconductor workpiece 15 are correctly oriented relative to one another, with minimal angular displacement between the primary alignment markers 12 and 16 of the first and the second semiconductor workpieces 11 and 15 (as depicted in FIG. 1C), or with zero (or negligible) angular displacement between the primary alignment markers 12 and 16 of the first and the second semiconductor workpieces 11 and 15 (as depicted in FIG. 1D). According to various aspects, with the first semiconductor workpiece 11 aligned within the central opening of the second semiconductor workpiece 15, both the first semiconductor workpiece 11 and the second semiconductor workpiece 15 may define a continuous spacing or gap between the first and the second semiconductor workpieces 11 and 15. In particular, this spacing or gap may encircle the first semiconductor workpiece 11. Subsequently, according to various aspects, this spacing or gap may be filled with bonding material to bond both semiconductor workpieces 11 and 15 together, described in detail later.

Additionally, according to various aspects, with reference to FIG. 1D, the alignment-detection assembly 130 or its sensor 131 (e.g. an optical sensor, vision system, etc.) may define a “region of interest” (ROI) or an “alignment window” 132 (e.g. a reference area or reference window) (depicted in phantom lines in FIG. 1D) within its field of view. According to various aspects, alignment between the first and the second semiconductor workpieces 11 and 15 may be considered successfully performed (or completed) by the system 100 when both the primary alignment markers 12 and 16 of the first and the second semiconductor workpieces 11 and 15 are located (or positioned) within a single, respective (e.g. discrete) ROI or alignment window 132.

According to various aspects, a single primary alignment marker 12 of the first semiconductor workpiece 11 and a single primary alignment marker 16 of the second semiconductor workpiece 15 may be sufficient for the alignment (e.g. corner alignment) process (i.e. between the first semiconductor workpiece 11 and the second semiconductor workpiece 15) to be performed by the system 100.

It is also envisaged that, according to various other aspects, the system 100 may utilize a plurality of primary alignment markers 12 (e.g. two or more corner regions) of the first semiconductor workpiece 11 and a corresponding number (e.g. plurality) of primary alignment markers 16 (e.g. two or more corner regions) of the second semiconductor workpiece 15 for alignment (e.g. angular alignment) of the first semiconductor workpiece 11 relative to the second semiconductor workpiece 15. For instance, with reference to FIG. 1D, the system 100 may align a first corner region (i.e. serving as a first primary alignment marker 12A) of the first semiconductor workpiece 11 with a first corner region (i.e. serving as a first primary alignment marker 16A) of the second semiconductor workpiece 15, align a second corner region (i.e. serving as a second primary alignment marker 12B) of the first semiconductor workpiece 11 with a second corner region (i.e. serving as a second primary alignment marker 16B) of the second semiconductor workpiece 15, align a third corner region (i.e. serving as a third primary alignment marker 12C) of the first semiconductor workpiece 11 with a third corner region (i.e. serving as a third primary alignment marker 16C) of the second semiconductor workpiece 15, and/or align a fourth corner region (i.e. serving as a fourth primary alignment marker 12D) of the first semiconductor workpiece 11 with a fourth corner region (i.e. serving as a fourth primary alignment marker 16D) of the second semiconductor workpiece 15. Accordingly, according to various other aspects, the system 100 may employ or utilize multiple ROIs or alignment windows 132, as illustrated in FIG. 1D-which, as some examples, may be defined either by a single optical sensor or multiple (e.g. four) optical sensors (e.g. each defining a discrete ROI 132) and/or a vision system, etc., of the alignment-detection assembly 130—for the alignment process (e.g. corner alignment) between the first semiconductor workpiece 11 and the second semiconductor workpiece 15.

Referring back to FIG. 1A, according to various aspects, the system 100 may include (e.g. further include) a bonding assembly (or arrangement, module, or unit) 140. According to various aspects, the platform 113 (or at least a portion of the platform 113) of the workpiece-support assembly 110 (i.e. having the aligned first and second semiconductor workpieces 11 and 15 thereon) may be located at or within the bonding assembly 140, or may overlap with the bonding assembly 140 (described later, with reference to FIGS. 1E and 1F).

According to various aspects, the bonding assembly 140 may be configured to dispense bonding material based on the detection of the primary alignment marker 12 of the first semiconductor workpiece 11 and the primary alignment marker 16 of the second semiconductor workpiece 15 (i.e. by the alignment-detection assembly 130).

In particular, according to various aspects, after the first semiconductor workpiece 11 and the second semiconductor workpiece 15 are aligned (or substantially aligned) (e.g. as determined by the alignment-detection assembly 130), the bonding assembly 140 of the system 100 may be configured to dispense bonding material. This bonding material may be configured to couple (e.g. adhere to and/or bond) the first semiconductor workpiece 11 and the second semiconductor workpiece 15 together. In particular, the bonding material may be a curable bonding material, described in detail later.

According to various aspects, the alignment-detection assembly 130 and the bonding assembly 140 may coordinate and communicate directly or via the controller 181, via wired communication or wireless communication, so that the bonding assembly 140 may initiate (e.g. automatically initiate) a bonding process for coupling the first semiconductor workpiece 11 and the second semiconductor workpiece 15 together, after the alignment process has been performed by a combination of the handling assembly 120 and the alignment-detection assembly 130, as previously described.

According to various aspects, the bonding assembly 140 may include a dispenser 141 configured to dispense the bonding material. According to various aspects, this dispenser 141 may be positioned over the workpiece-support assembly 110 (e.g. the platform 113).

FIG. 1E and FIG. 1F schematically depict a first variation of a bonding assembly of the system of FIG. 1A, according to various aspects.

With reference to FIG. 1E, according to various aspects, the bonding material may be a film (e.g. at least one single, continuous and/or uninterrupted and/or homogenous film or layer) of bonding material. According to various aspects, this film of bonding material may possess one or more properties which enable the film of bonding material to be laminated, adhered, and/or bonded to a surface (e.g. upper surface and/or bottom surface) of both the first semiconductor workpiece 11 and the second semiconductor workpiece 15, particularly, upon application of heat and/or pressure. Once laminated, the film of bonding material couples (or bonds) the first semiconductor workpiece 11 and the second semiconductor workpiece 15 together. Specifically, upon lamination, the film of bonding material forms a continuous support structure that holds the first semiconductor workpiece 11 and the second semiconductor workpiece 15 together.

As some examples, according to various aspects, the film of bonding material may include or may be any one or a combination of a dry film, Polyimide film, dielectric film, insulating film, and/or semiconductor film, etc. Specifically, according to various aspects, the bonding material may include or may be Ajinomoto Build-up Film (ABF) (e.g. which may include an ABF layer supported by a carrier or support layer, such as a Polyethylene Terephthalate (PET) layer). As an illustration, the ABF layer (e.g. ABF resin) may initially correspond to a dry film (pre-lamination), which may be laminated onto the surfaces of the semiconductor workpieces 11 and 15 upon application of heat and/or pressure. During lamination, the ABF resin may transform into a molten state under heat and/or pressure and may be subsequently cured into a solid state.

With reference to FIG. 1E, according to various aspects, the dispenser 141 of the bonding assembly 140 may include or may be a film-dispensing unit 143 configured to dispense (e.g. automatically dispense) the film of bonding material (e.g. ABF) over the bottom surfaces and/or over the upper surfaces of the first semiconductor workpiece 11 and the second semiconductor workpiece 15, respectively. For instance, with reference to FIG. 1E, the film-dispensing unit 143 may include at least one dispensing sub-unit 144 (e.g. which may include at least one roller dispenser) configured to dispense (e.g. automatically dispense) or apply the film of bonding material over the semiconductor workpieces 11 and 15. Specifically, as depicted in FIG. 1E, the film-dispensing unit 143 may include a first dispensing sub-unit 144A configured to dispense a first film of bonding material 151A over a first side (e.g. over the bottom surfaces) of both semiconductor workpieces 11 and 15 and may optionally and/or further include a second (or other) dispensing sub-unit 144B configured to dispense a second (or other) film of bonding material 151B over a second side (e.g. over the upper surfaces) of both semiconductor workpieces 11 and 15. Additionally, the film-dispensing unit 143 may further include at least one gathering sub-unit 145 (e.g. which may include at least one roller gatherer) which may cooperate with the dispensing sub-unit 144 by collecting or gathering (e.g. automatically collecting or gathering) remaining portions of the film(s) of bonding material (or gathering a carrier or support layer, e.g., PET layer, initially and/or temporarily supporting the bonding material that is subsequently “consumed” during lamination). Specifically, as depicted in FIG. 1E, the film-dispensing unit 143 may include a first gathering sub-unit 145A configured to coordinate with the first dispensing sub-unit 144A and may optionally and/or further include a second (or other) gathering sub-unit 145B configured to coordinate with the second dispensing sub-unit 144B. As an illustration, in FIG. 1E, one end of each film of bonding material may be coupled (e.g. secured or attached) to the dispensing sub-unit 144, while an opposite end of the film of bonding material may be coupled to the gathering sub-unit 145. The dispensing sub-unit 144 and the gathering sub-unit 145 may be synchronized to dispense a portion of the film of bonding material, while concurrently gathering any remaining portion of the film of bonding material (or gathering a carrier or support layer that remains post-lamination).

According to various aspects, with reference to FIG. 1E and FIG. 1F, the bonding assembly 140 may include or may be a compression molding unit (or a “mount-and-mold” unit) 142. This compression molding unit 142 may include a workpiece-holding portion configured to accommodate both the second semiconductor workpiece 15 as well as the first semiconductor workpiece 11 disposed within the central opening of the second semiconductor workpiece 15. Further, as shown, the compression molding unit 142 may include a first plate 142A (e.g. a bottom or lower molding plate) and a second plate 142B (e.g. a top or upper molding plate, opposite or over the first plate 142A), configured to be movable (e.g. automatically movable) relative to each other along a movement axis 40 extending across the workpiece-holding portion. According to various aspects, as shown in FIG. 1F, the first plate 142A and the second plate 142B may move (e.g. automatically move) toward each other to press the film(s) of bonding material 151A and/or 151B against the upper and/or bottom surfaces of the first semiconductor workpiece 11 and the second semiconductor workpiece 15. Additionally, heat may be applied or supplied (e.g. via heating elements, such as heaters or preheaters, which may be regulated by electricity) to the film(s) of bonding material 151A and/or 151B (for example, the film(s) of bonding material 151A and/or 151B may be heated above room temperature), thereby laminating the film(s) of bonding material 151A and/or 151B onto the first semiconductor workpiece 11 and the second semiconductor workpiece 15. Subsequently, the first plate 142A and the second plate 142B may move (e.g. automatically move) away from each other (e.g. for removal and/or subsequent processing of the first and second semiconductor workpieces 11 and 15).

Furthermore, according to various aspects, a release layer (e.g. a release liner or release film, possessing a non-stick property) may be provided or disposed between the semiconductor workpieces 11 and 15 and each of the first plate 142A and the second plate 142B. In particular, as an example, shown in FIG. 1E, the film-dispensing unit 143 may include a first release-layer-dispensing sub-unit 146A to dispense a first release layer 152A between the first plate 142A and the first film of bonding material 151A and may optionally and/or further include a second release-layer-dispensing sub-unit 146B to dispense a second release layer 152B between the second plate 142B and the second film of bonding material 151B. Additionally, the film-dispensing unit 143 may also include a first release-layer-gathering sub-unit 147A configured to coordinate with the first release-layer-dispensing sub-unit 146A and may optionally and/or further include a second release-layer-gathering sub-unit 147B configured to coordinate with the second release-layer-dispensing sub-unit 146B, to gather the first release layer 152A and the second release layer 152B, respectively.

According to various aspects, the platform 113 of the workpiece-support assembly 110 (or at least a region thereof) may be configured as the first plate 142A. Alternatively, the first plate 142A may be over (or overlapping) the platform 113 of the workpiece-support assembly 110.

As another example, according to various other aspects, the compression molding unit 142 may include, or may be fitted with, a dispenser 148 (see FIG. 1G) that is configured to dispense a bonding material in liquid form into the spaces or gaps between the first semiconductor workpiece 11 and the second semiconductor workpiece 15 (i.e. with the first semiconductor workpiece 11 disposed within the central opening of the second semiconductor workpiece 15). Here, the first plate 142A of the compression molding unit 142 (depicted in FIG. 1E and FIG. 1F) may be configured as a first molding plate, while the second plate 142B of the compression molding unit 142 may be configured as a second molding plate. These plates 142A and 142B may move towards each other and/or may respectively engage the first semiconductor workpiece 11 and the second semiconductor workpiece 15 to create or define a mold cavity, encompassing the spaces or gaps between the first semiconductor workpiece 11 and the second semiconductor workpiece 15. The dispenser 148 of the bonding assembly 140 may be configured to be in fluidic communication with the mold cavity, to dispense liquid bonding material into this mold cavity. Subsequently, the bonding material may be cured, solidifying into a single solid entity that bonds and couples the first semiconductor workpiece 11 and the second semiconductor workpiece 15 together. As some non-limiting examples, this curable liquid bonding material may be or may include a polymer, an epoxy or epoxy mold compound, silicone, polyimide, polyethersulfone, or polyacrylate, thermoplastic (e.g. moldable thermoplastic melt), thermoset resin (e.g. curable thermoset resin), etc., or any curable mold material or material composite, or any other suitable material or material composite. As some non-limiting examples, curing this liquid bonding material may involve thermal curing (e.g. within an oven or heating chamber of the bonding assembly 140), ultraviolet curing, room-temperature curing, etc.

FIG. 1G schematically depicts a second variation of the bonding assembly of the system of FIG. 1A, according to various aspects.

FIG. 1H schematically depicts the first semiconductor workpiece and the second semiconductor workpiece coupled via bonding material from the bonding assembly of FIG. 1G, according to various aspects.

Referring to FIG. 1G, according to various aspects, the dispenser 141 of the bonding assembly 140 may include or may be (in other words, may be configured as) at least one needle or nozzle dispenser 148, positioned over the platform 113. According to various aspects, the dispenser 148 may be configured to dispense a bonding material in liquid form into the spaces or gaps defined by the first semiconductor workpiece 11 and the second semiconductor workpiece 15 (i.e. with the first semiconductor workpiece 11 disposed within the central opening of the second semiconductor workpiece 15), so that (or until) the liquid bonding material fills (e.g. substantially or completely fills) the spaces or gaps between the first semiconductor workpiece 11 and the second semiconductor workpiece 15. In particular, according to various aspects, the bonding material may include or may be an adhesive or adhesive material or material composite that is dispensable in liquid form from the dispenser 148 of the bonding assembly 140.

According to various aspects, to prevent the adhesive bonding material from adhering to the platform 113 of the workpiece-support assembly 110 (i.e. that may be supporting the first and the second semiconductor workpieces 11 and 15), a release layer 152C (or release film, possessing a non-stick property) may be disposed between the semiconductor workpieces 11 and 15 and the platform 113, before the adhesive bonding material is dispensed by the dispenser 148 into the spaces or gaps between the first semiconductor workpiece 11 and the second semiconductor workpiece 15. According to various aspects, the release layer 152C may be provided (e.g. dispensed) via a film-dispensing unit of the bonding assembly 140 (e.g. which may be configured similarly or identically to the film-dispensing unit 143, described earlier).

Furthermore, according to various aspects, the sensor 131 of the alignment-detection assembly 130 of the system 100 of FIG. 1A may be configured to detect (or determine) when the spaces or gaps between the first semiconductor workpiece 11 and the second semiconductor workpiece 15 are filled (e.g. substantially or completely filled) with the adhesive bonding material, in turn prompting the dispenser 148 to cease dispensing the adhesive bonding material.

Subsequently, according to various aspects, with reference to FIG. 1H, the bonding assembly 140 may be configured to cure the liquid adhesive bonding material until it solidifies. In particular, the bonding assembly 140 may be configured to automatically cure the liquid adhesive bonding material after the dispenser 148 has filled the spaces or gaps between the first semiconductor workpiece 11 and the second semiconductor workpiece 15 with the liquid adhesive bonding material. According to various aspects, once cured, the cured adhesive bonding material (or solid adhesive material) 158 may couple (e.g. affix or bond) the first semiconductor to the second semiconductor workpiece 15. As some non-limiting examples, the bonding assembly 140 may be configured to cure the liquid adhesive bonding material through any one or more of the following processes: thermal curing (e.g. within an oven or heating chamber, or using a heating element, of the bonding assembly 140), ultraviolet curing (e.g. using an ultraviolet light source 149 of the bonding assembly 140), room-temperature curing, etc.

FIG. 1I schematically depicts a fiducial-marking assembly of the system of FIG. 1A, according to various aspects.

FIG. 1J schematically depicts fiducials formed on the second semiconductor workpiece through the fiducial-marking assembly of FIG. 1I, according to various aspects.

According to various aspects, the system 100 may include (e.g. further include) a fiducial-marking assembly (or arrangement, module, or unit) 160 configured to create at least one fiducial on the second semiconductor workpiece 15. According to various aspects, the fiducial-marking assembly 160 may be positioned over and/or oriented towards the workpiece-support assembly 110 (e.g. the platform 113), on which the second semiconductor workpiece 15 may be disposed. As some non-limiting examples, the fiducial-marking assembly 160 may include one or more tool(s), such as a drill (e.g. a laser drill or mechanical drill) 161, an etching tool, a lithography tool, a Focused Ion Beam tool, an Electrochemical Discharge Machining tool, etc., for this purpose.

According to various aspects, the at least one fiducial formed may serve as at least one corresponding secondary alignment marker 17 (see FIG. 1J) on the second semiconductor workpiece 15, which may be compared to (previously formed or previously provided) secondary alignment marker(s) 13 on the first semiconductor workpiece 11 for ensuring that the first and the second semiconductor workpieces 11 and 15 maintain proper angular alignment relative to each other.

To illustrate, referring to FIG. 1I, according to various aspects, the first semiconductor workpiece 11 may include (e.g. may be provided with or may have thereon) at least one secondary alignment marker 13. According to various aspects, each secondary alignment marker 13 of the first semiconductor workpiece 11 may be a hole (e.g. a blind hole or a through-hole) on the first semiconductor workpiece 11. As an example, illustrated in FIG. 1I, the first semiconductor workpiece 11 may have four secondary alignment markers 13 at the four corner regions of the (e.g. a square-shaped) first semiconductor workpiece 11. Nevertheless, it is envisaged that, according to various other aspects, the first semiconductor workpiece 11 may include or have any other number of secondary alignment marker(s), which may (e.g. optionally) be situated anywhere on the first semiconductor workpiece 11 other than at the corner region(s) thereof.

According to various aspects, the alignment-detection assembly 130 of the system 100 of FIG. 1A may be configured to detect the secondary alignment marker(s) 13 of the first semiconductor workpiece 11. Specifically, according to various aspects, the alignment-detection assembly 130 (e.g. its sensor 131) may be configured (e.g. programmed or preprogrammed) to identify each hole (e.g. at the peripheral region) of the first semiconductor workpiece 11 (e.g. having a predetermined size or diameter) as a secondary alignment marker 13 of the first semiconductor workpiece 11.

Referring to FIG. 1I, according to various aspects, the fiducial-marking assembly 160 (e.g. its drill 161) may be actuable (e.g. operated or movable, for example, relative to the workpiece-support assembly 110) based on the detection (i.e. by the alignment-detection assembly 130) of the secondary alignment marker(s) 13 of the first semiconductor workpiece 11. Specifically, the alignment-detection assembly 130 and the fiducial-marking assembly 160 may coordinate and communicate directly or via the controller 181, via wired communication or wireless communication, so that the fiducial-marking assembly 160 may initiate (e.g. automatically initiate) a fiducial forming process on the second semiconductor workpiece 15 (e.g. after the system 100 detects that the corner alignment process and/or the bonding process, as previously described, are completed).

According to various aspects, of this fiducial forming process, the fiducial-marking assembly 160 (e.g. its drill 161) may be configured to form at least one secondary alignment marker 17 on the second semiconductor workpiece 15 that is associated (or paired) with the at least one secondary alignment marker 13 of the first semiconductor workpiece 11. According to various aspects, when the fiducial forming process is initiated after the bonding process, the fiducial forming process may be performed, for example, based on real-time detection by the alignment-detection assembly 130 of the at least one secondary alignment marker 13 of the first semiconductor workpiece 11 (e.g. when the semiconductor workpieces 11 and 15 are bonded with a film of bonding material on a single side, such as the bottom surface, of both semiconductor workpieces 11 and 15, or when the semiconductor workpieces 11 and 15 are bonded using curable liquid bonding material or adhesive). As another example, the fiducial forming process may be performed based on stored positional data (e.g. stored by the alignment-detection assembly 130 in a memory module 182 of the system 100) which contains positional information on the at least one secondary alignment marker 13 of the first semiconductor workpiece 11 (e.g. prior to bonding of the semiconductor workpieces 11 and 15 with a pair of films of bonding material on both their upper and bottom surfaces). It is also envisaged that, in various aspects, the fiducial forming process may be initiated after (e.g. immediately after) the corner alignment process, but before the bonding process.

According to various aspects, each secondary alignment marker 17 formed by the fiducial-marking assembly 160 may be a hole (e.g. a blind hole or a through-hole) on the second semiconductor workpiece 15. According to various aspects, a number of secondary alignment maker(s) formed on the second semiconductor workpiece 15 (i.e. by the fiducial-marking assembly 160) may be equal to a number of secondary alignment marker(s) 13 on the first semiconductor workpiece 11.

According to various aspects, each secondary alignment marker 17 that is formed on the second semiconductor workpiece 15 may be associated and/or aligned with a respective secondary alignment marker 13 of the first semiconductor workpiece 11. For instance, as depicted in FIG. 1J, each secondary alignment marker 17 of the second semiconductor workpiece 15 may be adjacent and/or proximal a respective primary alignment marker 12 of the first semiconductor workpiece 11 and/or located within a respective (e.g. a discrete) ROI or alignment window 132 of the alignment-detection assembly 130 (or its sensor 131). In this manner, each secondary alignment marker 17 of the second semiconductor workpiece 15 may be more easily compared with a corresponding secondary alignment marker 13 of the first semiconductor workpiece 11, to ensure that both the first semiconductor workpiece 11 and the second semiconductor workpiece 15 maintain proper angular alignment (e.g. throughout or during any subsequent process or location within the system 100).

According to various aspects, the alignment-detection assembly 130 (e.g. its sensor 131) may be configured to verify angular alignment between the first semiconductor workpiece 11 and the second semiconductor workpiece 15. This may be conducted, for example, by detecting the at least one secondary alignment marker 13 of the first semiconductor workpiece 11 and the at least one secondary alignment marker 17 of the second semiconductor workpiece 15 and determining whether they are aligned or misaligned with each other. According to various aspects, the alignment-detection assembly 130 may be configured to perform this process downstream of the fiducial-marking assembly 160 (e.g. near or at an end of the system 100, such as at an unloading bay 114, described later), particularly if the at least one secondary alignment marker 13 of the first semiconductor workpiece 11 and the at least one secondary alignment marker 17 of the second semiconductor workpiece 15 are not covered (e.g. by any build-up layer or ABF) and are thus still visible to the alignment-detection assembly 130. According to various aspects, if the alignment-detection assembly 130 identifies angular misalignment between the first semiconductor workpiece 11 and the second semiconductor workpiece 15, the system 100 may flag and/or mark these misaligned semiconductor workpieces 11 and 15 as being misaligned. In various other aspects, the handling assembly 120 of the system 100 of FIG. 1A may be configured to remove the misaligned semiconductor workpieces 11 and 15 from the system 100, preventing them from reaching the unloading bay 114.

With reference to FIG. 1A and FIG. 1J, according to various aspects, the alignment-detection assembly 130 may be configured to detect the secondary alignment marker(s) 17 of the second semiconductor workpiece 15 after they are formed by the fiducial-marking assembly 160. Specifically, according to various aspects, the alignment-detection assembly 130 (e.g. its sensor 131) may be configured (e.g. programmed or preprogrammed) to identify each newly formed hole on the second semiconductor workpiece 15 as a secondary alignment marker 17 of the second semiconductor workpiece 15.

Additionally, with reference to FIG. 1A, according to various aspects, the system 100 may include (e.g. further include) a trimming assembly 170 configured to trim or remove material from the second semiconductor workpiece 15 based on the secondary alignment marker(s) 17 of the second semiconductor workpiece 15. For instance, the alignment-detection assembly 130 and the trimming assembly 170 may coordinate and communicate directly or via the controller 181, via wired communication or wireless communication. This communication may enable the trimming assembly 170 to initiate (e.g. automatically initiate) a trimming process on the second semiconductor workpiece 15 (e.g. once the system 100 detects that the fiducial forming process is completed). As some examples, the trimming assembly 170 may include a cutter 171, such as a laser cutter, mechanical cutter, tool bit, router bit, saw, blade, etc., or any other types of cutter. According to various aspects, this cutter 171 may be positioned over and/or oriented towards the workpiece-support assembly 110 (e.g. the platform 113), on which the second semiconductor workpiece 15 may be disposed.

As an example, according to various aspects, the trimming assembly 170 may be configured to trim or remove material from an outer peripheral region or outer edge(s) of the second semiconductor workpiece 15 based on, or according to (e.g. by following or tracing), the secondary alignment marker(s) 17 of the second semiconductor workpiece 15. Alternatively, as another example, according to various other aspects, the trimming assembly 170 may be configured to trim or remove material based on a predetermined measurement or dimension measured (e.g. by the alignment-detection assembly 130) from the outer edges or perimeter of the second semiconductor workpiece 15.

According to various aspects, after the trimming process, the remaining (i.e. assembled) first and second semiconductor workpieces 11 and 15 may correspond to an (assembled) “hybrid panel” (i.e. a finished product).

According to various aspects, after the system 100 detects the completion of the trimming process, the handling assembly 120 may be configured to move or place the hybrid panel onto the unloading bay 114. For instance, as illustrated in FIG. 1A, the handling assembly 120 may include a manipulator (e.g. a third manipulator) 121C located downstream of the trimming assembly 170 and/or positioned between the trimming assembly 170 and the unloading bay 114, for transferring the hybrid panel to the unloading bay 114. As depicted in FIG. 1A, the unloading bay 114 may be situated at an end of the system 100, downstream of the bonding assembly 140, the fiducial-marking assembly 160, and the trimming assembly 170. According to various aspects, the unloading bay 114 may be part of, or be an element or component of, the workpiece-support assembly 110.

With reference to FIG. 1A, according to various aspects, as an illustration, the first and the second manipulators 121A and 121B of the handling assembly 120 may be downstream (e.g. immediately downstream) of both the first and the second workpiece-loading bays 111A and 111B. Next, the conveyor 112 may be downstream (e.g. immediately downstream) of both the first and the second manipulators 121A and 121B. Next, the bonding assembly 140 may be downstream (e.g. immediately downstream) of the conveyor 112. Next, the fiducial-marking assembly 160 may be downstream (e.g. immediately downstream) of the bonding assembly 140. Next, the trimming assembly 170 may be downstream (e.g. immediately downstream) of the fiducial-marking assembly 160. Next, the third manipulator 121C of the handling assembly 120 may be downstream (e.g. immediately downstream) of the trimming assembly 170. Finally, the unloading bay 114 of the workpiece-support assembly 110 may be downstream (e.g. immediately downstream) of the third manipulator 121C of the handling assembly 120.

It is also envisaged that, according to various aspects, any two or more assemblies of the system 100 of FIG. 1A may be located at (or within) a same location, area, or region (or chamber) of the system 100. For instance, as a non-limiting example, the fiducial-marking assembly 160 and the trimming assembly 170 may be located at within a same region (or chamber), so that they may respectively and sequentially perform a fiducial forming process following by a trimming process without a need to move the semiconductor workpieces 11 and 15 themselves during these particular processes. It is also envisaged that, according to various aspects, any two or more assemblies of the system 100 may overlap. For instance, the platform 113 of the workpiece-support assembly 110 may be elongated and/or extending along (or across) at least the bonding assembly 140, the fiducial-marking assembly 160 and the trimming assembly 170. Accordingly, in this example, the handling assembly 120 may be configured to move the semiconductor workpieces 11 and 15 from one end (or one segment) of the platform 113 (e.g. where the bonding assembly 140 may be situated) to another end (or another segment) of the platform 113 (e.g. where the fiducial-marking assembly 160 and the trimming assembly 170 may be situated).

With reference to FIG. 1A, according to various aspects, any one or more or each (e.g. all) of the workpiece-support assembly 110, the handling assembly 120, the alignment-detection assembly 130, the bonding assembly 140, the fiducial-marking assembly 160, and/or the trimming assembly 170 may be a respective modular sub-assembly (or a respective module) of the system 100. Accordingly, it is envisaged that, according to various aspects, any one or more or each (e.g. all) of the workpiece-support assembly 110, the handling assembly 120, the alignment-detection assembly 130, the bonding assembly 140, the fiducial-marking assembly 160, and/or the trimming assembly 170 may be positioned (and/or repositioned) within the system 100 in any (e.g. other) suitable manner.

It is also envisaged that, according to various other aspects, any one or more or each (e.g. all) of the workpiece-support assembly 110, the handling assembly 120, the alignment-detection assembly 130, the bonding assembly 140, the fiducial-marking assembly 160, and/or the trimming assembly 170 may be integral and/or at a fixed position within the system 100.

According to various aspects, the various assemblies of the system 100 may be electrically connected (or coupled) to one another via wired connection or via wireless connection and/or may communicate (or may be in communication with) one another via wired communication or wireless communication.

Accordingly, the various assemblies described herein may be assembled to form a system, such as the system 100 of FIG. 1A.

According to various aspects, of the system 100, the handling assembly 120 may be configured to move the first semiconductor workpiece 11 and/or the second semiconductor workpiece 15 relative to any one or more or all of the workpiece-support assembly 110, the alignment-detection assembly 130, the bonding assembly 140, the fiducial-marking assembly 160, and/or the trimming assembly 170. Accordingly, according to various aspects, the handling assembly 120 may be movable relative to any one or more or each (e.g. all) of the workpiece-support assembly 110, the alignment-detection assembly 130, the bonding assembly 140, the fiducial-marking assembly 160, and/or the trimming assembly 170.

According to various other aspects, any two or more of the workpiece-support assembly 110, the handling assembly 120, the alignment-detection assembly 130, the bonding assembly 140, the fiducial-marking assembly 160, and/or the trimming assembly 170 may be movable (e.g. configured to be automatically movable within the system 100) relative to any other assembly, arrangement, unit, or module of the system 100.

According to various aspects, the controller 181 may be electrically connected (e.g. via wired or wireless connection) to any one or more or all of the alignment-detection assembly 130 (e.g. its sensor 131), the handling assembly 120 (e.g. its at least one manipulator 121), the bonding assembly 140 (e.g. its dispenser 141 or 148), the fiducial-marking assembly 160 (e.g. its drill 161), and/or the trimming assembly 170 (e.g. its cutter 171). Thus, the controller 181 may communicate with and/or control any one or more or all of the alignment-detection assembly 130 (e.g. its sensor 131), the handling assembly 120 (e.g. its at least one manipulator 121), the bonding assembly 140 (e.g. its dispenser 141 or 148), the fiducial-marking assembly 160 (e.g. its drill 161), and/or the trimming assembly 170 (e.g. its cutter 171) that the controller 181 may be electrically connected with. As an illustration, the controller 181 may be electrically connected to at least the alignment-detection assembly 130 and the handling assembly 120, such that the controller 181 may control the handling assembly 120 (e.g. its at least one manipulator 121) to place the first semiconductor workpiece 11 within the central opening of the second semiconductor workpiece 15 upon detection of the primary alignment marker 12 of the first semiconductor workpiece 11 and the primary alignment marker 16 of the second semiconductor workpiece 15 by the alignment-detection assembly 130. As another illustration, the controller 181 may be electrically connected to at least the handling assembly 120 and the bonding assembly 140, such that the controller 181 may control the bonding assembly 140 (e.g. its dispenser 141 or 148) to dispense bonding material upon completion of the placement of the first semiconductor workpiece 11 within the central opening of the second semiconductor workpiece 15 by the handling assembly 120. As yet another illustration, the controller 181 may be electrically connected to at least the bonding assembly 140 and the fiducial-marking assembly 160, such that the controller 181 may control the fiducial-marking assembly 160 (e.g. its drill 161) to form the hole on the second semiconductor workpiece 15 (i.e. which serves as the secondary alignment marker 17 of the second semiconductor workpiece 15) upon completion of the dispensing of the bonding material by the bonding assembly 140.

FIG. 2A schematically depicts the first semiconductor workpiece with a plurality of secondary alignment markers, according to various aspects.

FIG. 2B is a cross-sectional view of the first semiconductor workpiece, taken along line A-A of FIG. 2A, according to various aspects.

According to various aspects, with reference to FIG. 2A and FIG. 2B, each secondary alignment marker 13 of the first semiconductor workpiece 11 may include or may be a hole extending between the upper surface and the bottom surface (herein may be referred to as “primary faces”) of the first semiconductor workpiece 11. As depicted in FIG. 2B, each secondary alignment marker 13 of the first semiconductor workpiece 11 may be a through-hole spanning the entire thickness of the first semiconductor workpiece 11, from its first primary face (e.g. upper surface) to its second primary face (e.g. bottom surface) opposite the first primary face. Alternatively, according to various other aspects (not shown), each secondary alignment marker 13 of the first semiconductor workpiece 11 may be a blind-hole (e.g. with an opening at only one primary face, such as the upper surface, of the first semiconductor workpiece 11). Furthermore, according to various aspects, a hole axis of each hole serving as the secondary alignment marker 13 of the first semiconductor workpiece 11 may be perpendicular (or substantially perpendicular) to the primary faces of the first semiconductor workpiece 11, corresponding to a vertical (or substantially vertical) orientation.

With reference to FIG. 2A, according to various aspects, each hole serving as the secondary alignment marker 13 of the first semiconductor workpiece 11 may be a circular-shaped hole (e.g. having a circle or circular cross-sectional profile). A diameter (e.g. a uniform diameter, or an average diameter) of each hole (e.g. circular-shaped hole) serving as the secondary alignment marker 13 of the first semiconductor workpiece 11 may range between approximately 50 μm and approximately 5 mm (in other words, the range may include 50 μm and 5 mm). Specifically, according to various aspects, each hole serving as the secondary alignment marker 13 of the first semiconductor workpiece 11 may have an average diameter between approximately 1 mm to approximately 2 mm.

Alternatively, in various other aspects, each hole serving as the secondary alignment marker 13 of the first semiconductor workpiece 11 may be non-circular in shape (e.g. square, triangular, etc.) and/or may have any other suitable size.

In particular, a size (e.g. diameter and/or opening) of each hole serving as the secondary alignment marker 13 of the first semiconductor workpiece 11 may be larger than that of each via (e.g. through glass via) 14 (see FIG. 2B) of the first semiconductor workpiece 11. As shown in FIG. 2B, the first semiconductor workpiece 11 may include at least one via (e.g. through glass via) 14, which may include or may be filled with a conductive material, such as metal (e.g. copper). According to various aspects, such a configuration may ensure that during a “via fill process”-such as a plating (e.g. electroplating) process-primarily intended to fill the at least one via 14 with conductive material, the holes serving as the secondary alignment markers 13 of the first semiconductor workpiece 11 would not get filled (or would not get completely filled) with the conductive material. According to various aspects, this, in turn, may enhance visibility of the holes serving as secondary alignment markers 13 of the first semiconductor workpiece 11 (e.g. during any downstream or subsequent processes). According to various aspects, the larger size of these holes compared to the via(s) (e.g. standard via(s)) 14 make them more visibly distinguishable from the via(s) 14, facilitating their identification and/or detection as secondary alignment markers 13 (i.e. by the alignment-detection assembly 130 of the system 100 of FIG. 1A). According to various aspects, these secondary alignment markers 13 of the first semiconductor workpiece 11 may serve as visual reference points, aiding in alignment and calibration during any downstream or subsequent processes within the system 100 of FIG. 1A.

According to various aspects, with reference to FIG. 2A, each secondary alignment marker 13 may be situated within a peripheral region 11A of the first semiconductor workpiece 11. This peripheral region 11A may encompass the outer edges or perimeter of the first semiconductor workpiece 11 and extend inward by a predetermined dimension. For example, the predetermined dimension (or an average thereof) may range between approximately 50 μm and approximately 20 mm (in other words, the range may include 50 μm and 20 mm), measured inward from the outer edges or perimeter of the first semiconductor workpiece 11. According to various aspects, this outer peripheral region 11A of the first semiconductor workpiece 11 may be distinct from an inner central (or an active) region 11B of the first semiconductor workpiece 11, where (primary) functional elements, circuits, dies, etc., may be located. Accordingly, this peripheral region 11A of the first semiconductor workpiece 11 may be termed a “Keep-Out Zone (KOZ)”, specifically, a “Back End (BE) KOZ”, surrounding or encircling the inner central (or active) region 11B of the first semiconductor workpiece 11.

According to various aspects, situating the secondary alignment markers 13 in the peripheral region 11A (or the BE KOZ) of the first semiconductor workpiece 11 may ensure that they do not interfere with (primary) operational elements of the first semiconductor workpiece 11, while still serving as accurate alignment references for various downstream processes.

Furthermore, according to various aspects, when the first semiconductor workpiece 11 includes a plurality of secondary alignment markers 13, they may be similar or identical (e.g. in shape, and/or size, etc.) to one another. Particularly, if the first semiconductor workpiece 11 has a rotationally symmetric shape, such as a square shape or a circle shape (e.g. with at least fourfold rotational symmetry), the secondary alignment markers 13 may be identical and/or positioned symmetrically about a first axis of symmetry (e.g. a x-axis) of the first semiconductor workpiece 11 and a second axis of symmetry (e.g. a y-axis) which may be perpendicular to the first axis of symmetry and intersecting the first axis of symmetry at the center of the first semiconductor workpiece 11.

However, it is also envisaged that, in various other aspects, at least two or more or all of the secondary alignment markers 13 may vary in shape and/or in size from one another and/or may be positioned non-symmetrically within the peripheral region 11A (or the BE KOZ) the first semiconductor workpiece 11.

Additionally, according to various aspects, each secondary alignment marker 13 of the first semiconductor workpiece 11 may be associated with and/or aligned to a respective primary alignment marker 12 of the first semiconductor workpiece 11. For instance, if the primary alignment marker 12 is a corner region of the first semiconductor workpiece 11, the secondary alignment marker 13 may be situated along a diagonal (reference) axis (not shown) that intersects that corner region. As an example, depicted in FIG. 2A, the first semiconductor workpiece 11 may include four secondary alignment markers (e.g. holes) 13 at the four corner regions (i.e. which serve as the primary alignment markers 12) of the first semiconductor workpiece 11.

According to various aspects, the system 100 described in FIG. 1A may be configured to form the secondary alignment marker(s) 13 on the first semiconductor workpiece 11. Specifically, each secondary alignment marker 13 may be created by the fiducial-marking assembly 160 of the system 100 after the first semiconductor workpiece 11 is loaded into the system 100 (e.g. via the first workpiece-loading bay 111A of the system 100), but before any secondary alignment marker 17 (shown in FIG. 1J) is formed on the second semiconductor workpiece 15.

As an example, according to various aspects, the fiducial-marking assembly 160 of the system 100 of FIG. 1A may include a tool, such as a drill (e.g. a laser drill or mechanical drill) 161, an etching tool, a lithography tool, a Focused Ion Beam (FIB) tool, an Electrochemical Discharge Machining (ECDM) tool, etc. This tool may be used to form the secondary alignment marker(s) 13 (e.g. hole(s)) on the first semiconductor workpiece 11 while it is supported on the workpiece-support assembly 110 (e.g. the platform 113) of the system 100 of FIG. 1A. According to various aspects, the fiducial-marking assembly 160 may be movable relative to the workpiece-support assembly 110 (e.g. the platform 113) to ensure precise formation and placement of the secondary alignment marker(s) 13 on the first semiconductor workpiece 11.

Additionally, according to various aspects, the alignment-detection assembly 130 (e.g. its sensor 131) of the system 100 of FIG. 1A may be configured to identify the BE KOZ on the first semiconductor workpiece 11 (e.g. by identifying and detecting the peripheral edges of the first semiconductor workpiece 11).

According to various aspects, once a first secondary alignment marker (e.g. a first hole) 13 is formed (e.g. at a first corner region within the BE KOZ) on the first semiconductor workpiece 11, the fiducial-marking assembly 160 and the alignment-detection assembly 130 may coordinate to form a second secondary alignment marker (e.g. a second hole) 13 using at least the first secondary alignment marker 13 (that was previously formed) as a reference point.

It is also envisaged that, according to various aspects, the fiducial-marking assembly 160 and the alignment-detection assembly 130 may coordinate to form any secondary alignment marker 13 on the first semiconductor workpiece 11 using a previously formed via (e.g. through glass via) 14 as a reference point. Conversely, the system 100 (e.g. a combination of a laser drill of the system 100 and the alignment-detection assembly 130) may be configured to form a via (e.g. through glass via) 14 on the first semiconductor workpiece 11 using a previously formed secondary alignment marker 13 as a reference point.

Alternatively, according to various other aspects, each secondary alignment marker 13 may be created on the first semiconductor workpiece 11 before it is loaded into the system 100. In other words, according to various other aspects, the first semiconductor workpiece 11 may already include at least one secondary alignment marker 13. Examples of methods of forming these secondary alignment marker(s) 13 on the first semiconductor workpiece 11 include drilling (e.g. laser drilling, mechanical drilling, etc.), lithography patterning, etching (e.g. chemical etching, plasma etching, etc.), FIB milling, ECDM, etc., or any other suitable process.

FIG. 2C schematically depicts the first semiconductor workpiece and the second semiconductor workpiece assembled together, according to various aspects.

FIG. 2D is a cross-sectional view of the assembled first semiconductor workpiece and second semiconductor workpiece, taken along line AA-AA of FIG. 2C, according to various aspects.

According to various aspects, with reference to FIG. 2C and FIG. 2D, the secondary alignment markers (e.g. holes) 13 in the first semiconductor workpiece 11 may be filled with material to minimize or eliminate “air gaps” in the finished hybrid panel, thereby preventing moisture accumulation within such gaps. According to various aspects, the material used may possess one or more properties, such as being non-magnetic (or magnetic), curable (e.g. capable of transitioning from a liquid to a solid state through a curing process), heat-resistant, dielectric, and/or insulating (e.g. electrically insulating), etc. It is also envisaged that other materials suitable for “plugging” the secondary alignment markers (e.g. holes) 13 of the first semiconductor workpiece 11 to prevent “air gaps” may also be employed. For example, the material may be or may include polymer or ABF resin (e.g. from a build-up layer or from ABF). In particular, the material may correspond to (e.g. may be similar or identical to), or may be, the bonding material (e.g. introduced during, or after, the bonding process, described earlier, depending on the initiation timing of the earlier described fiducial forming process relative to the bonding process). Accordingly, according to various aspects, the material for plugging the secondary alignment markers (e.g. holes) 13 of the first semiconductor workpiece 11 may differ (e.g. may differ in composition or may include at least one element that is different) from the material that fills the at least one via (e.g. through glass via) 14.

Similarly, according to various aspects, the secondary alignment markers (e.g. holes) 17 of the second semiconductor workpiece 15 may also be filled with a corresponding (e.g. similar or identical) material suitable for “plugging” the secondary alignment markers (e.g. holes) 17 of the second semiconductor workpiece 15 to minimize or eliminate “air gaps”.

As an illustration, depicted in FIG. 2D, the coupling between the first and the second semiconductor workpieces 11 and 15 may involve the integration of one or more build-up layers or ABF (i.e. film(s) of bonding material) 251A and/or 251B, along with bonding material (e.g. from the build-up layer(s) or ABF 251A and/or 251B, or which may include or may be an adhesive bonding material 258) which fills the gaps between the side surfaces of the first semiconductor workpiece 11 and the second semiconductor workpiece 15. According to various aspects, this cohesive approach may not only reinforce the bond between the first and the second semiconductor workpieces 11 and 15, but may also enhance an overall structural integrity of the assembled hybrid panel.

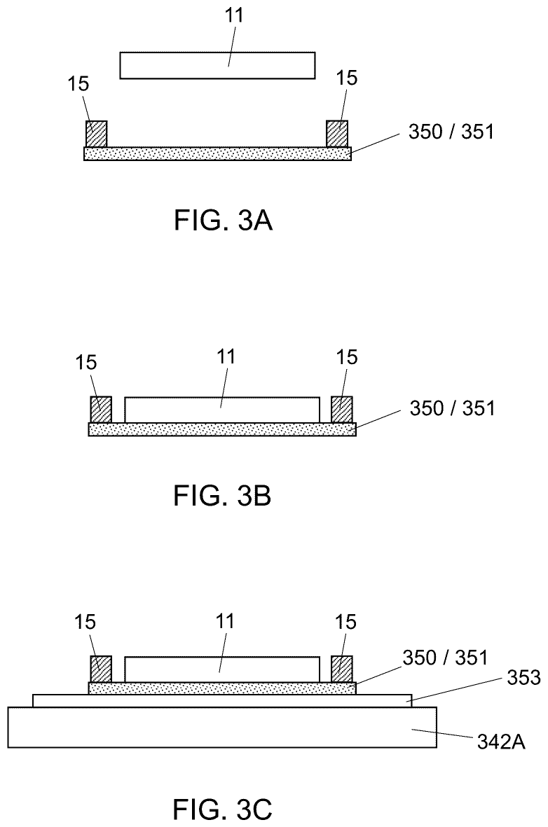

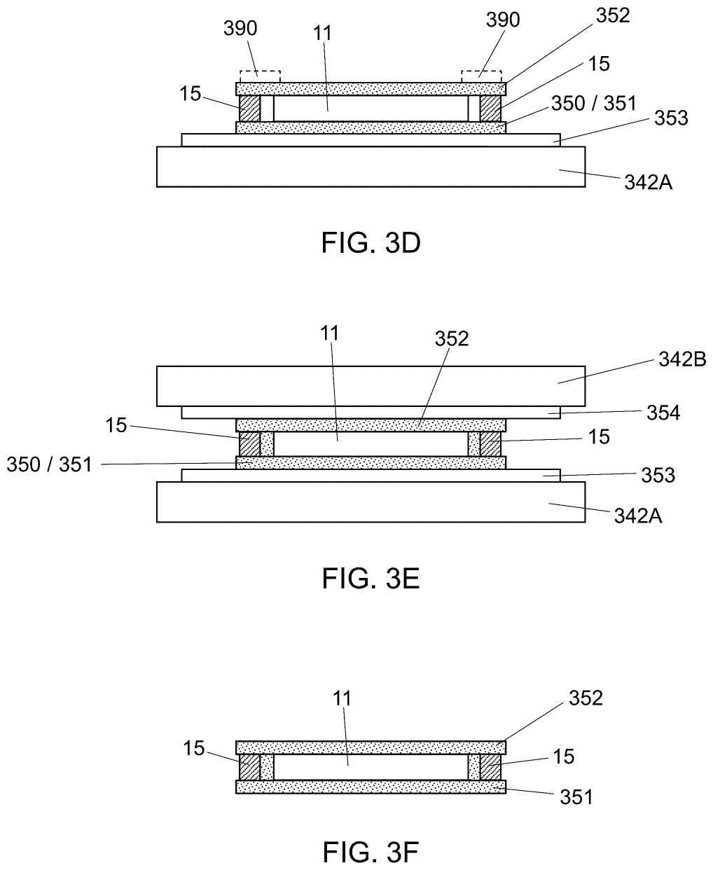

FIG. 3A to FIG. 3F depict a process of bonding the first semiconductor workpiece and the second semiconductor workpiece via compression molding, according to various aspects.

According to various aspects, with reference to FIG. 3A to FIG. 3C, the process may involve positioning (or placing) the first semiconductor workpiece 11 within the central opening (e.g. through-hole opening) of the second semiconductor workpiece 15 (e.g. with the aid of the handling assembly 120, or a combination of both the handling assembly 120 and the alignment-detection assembly 130, of the system 100 of FIG. 1A, as previously described).

Particularly, as depicted in FIG. 3B, the first semiconductor workpiece 11 and the second semiconductor workpiece 15 may initially be supported on either (i) a carrier film 350 or (ii) a first film of bonding material (e.g. dry film, ABF, etc.) 351.

As illustrated in FIG. 3C, this (i) carrier film 350 or (ii) first film of bonding material 351 may, in turn, be disposed or placed over or on a first plate 342A-which may correspond to (e.g. may be similar or identical to), or may be, the first plate 142A of the compression molding unit 142 of the bonding assembly 140 of the system 100 of FIG. 1A, as previously described. Accordingly, the first plate 342A may also serve as a mounting stage for the first and the second semiconductor workpieces 11 and 15 on (i) the carrier film 350 or (ii) the first film of bonding material 351. Additionally, with reference to FIG. 3C, a first release layer (or release film) 353 may be disposed between either of (i) the carrier film 350 or (ii) the first film of bonding material 351 and the (underlying) first plate 342A.

Next, with reference to FIG. 3D, another film of bonding material 352 (e.g. a second film of bonding material, such as dry film, ABF, etc.) may be disposed or applied over and/or on the first semiconductor workpiece 11 and the second semiconductor workpiece 15, in particular, over their upper surfaces.

As depicted in FIG. 3D, according to various aspects, one or more stiffeners 390 (e.g. which may be composed of any suitable rigid material or material composite, such as metal, Aluminium Oxide, rigid polymer, Silicon, glass fiber composite or glass fiber reinforced composite, glass fiber reinforced polymer, fiberglass, etc.) may (e.g. optionally) be disposed over and/or on the first semiconductor workpiece 11 and/or the second semiconductor workpiece 15, if needed. According to various aspects, these stiffeners 390 may be discrete components or they may form a continuous stiffener frame. Furthermore, they may be directly attached onto the first semiconductor workpiece 11 and/or the second semiconductor workpiece 15 (e.g. at their peripheral edge region or at any region where structural reinforcement is desired), or they may be directly attached onto an exposed surface of the film of bonding material 352 (e.g. with the film of bonding material 352 sandwiched between the one or more stiffeners 390 and the semiconductor workpieces 11 and 15). According to various aspects, the handling assembly 120, or a combination of both the handling assembly 120 and the alignment-detection assembly 130 (e.g. configured to identify and detect the one or more stiffeners 390), may be configured to move and place (e.g. in an automatic manner) the one or more stiffeners 390 over and/or on the first semiconductor workpiece 11 and/or the second semiconductor workpiece 15.

Subsequently, with reference to FIG. 3E, a second plate 342B-which may correspond to (e.g. may be similar or identical to), or may be, the second plate 142B of the compression molding unit 142 of the bonding assembly 140 of the system 100 of FIG. 1A, as previously described—as well as a second release layer (or release film) 354 may be brought (or moved) towards the first and the second semiconductor workpieces 11 and 15, to apply pressure to the semiconductor workpieces 11 and 15 and the film(s) of bonding material 351/352 they may be interfaced with. Additionally, the compression molding unit 142 may also apply heat, which may cause the film(s) of bonding material 351/352 to laminate onto the first and the second semiconductor workpieces 11 and 15, respectively.

Optionally, if carrier film 350 was initially used in lieu of the first film of bonding material 351, the carrier film 350 may finally be removed, and the first and the second semiconductor workpieces 11 and 15 (i.e. together with a laminated film of bonding material 352) may (e.g. optionally) be flipped (e.g. with the aid of a flipper or any suitable repositioning mechanism). Next, the earlier-described lamination process may then be repeated on the surfaces of the first and the second semiconductor workpieces 11 and 15 where the carrier film 350 was previously situated.

Lastly, the first plate 342A and the second plate 342B may be separated from each other to retrieve the laminated first and second semiconductor workpieces 11 and 15.

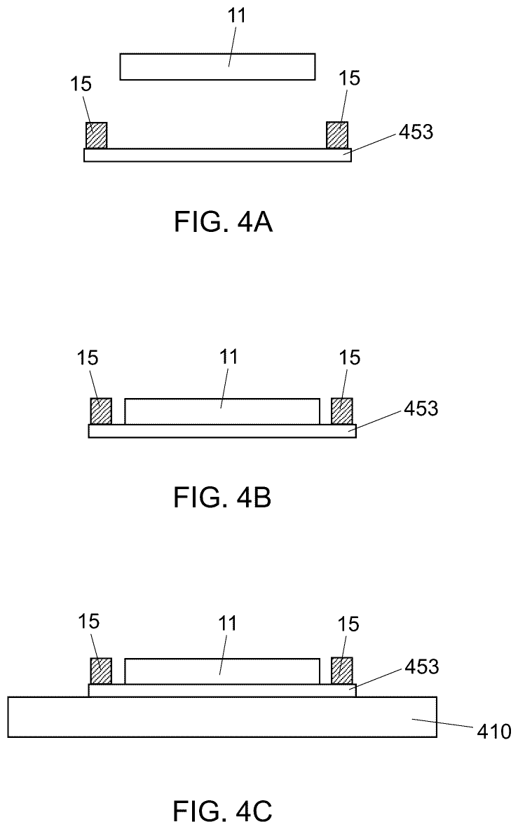

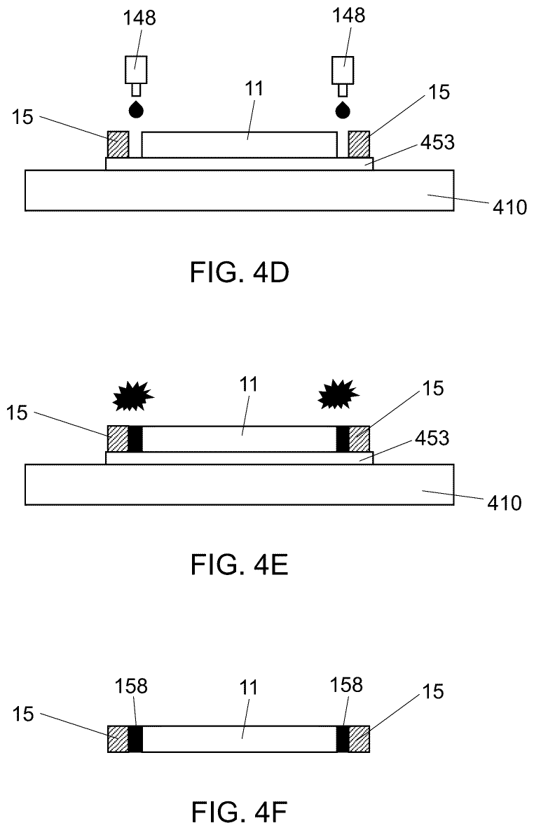

FIG. 4A to FIG. 4F depict a process of bonding the first semiconductor workpiece and the second semiconductor workpiece using an adhesive, according to various aspects.

According to various aspects, with reference to FIG. 4A to FIG. 4C, the process may involve positioning (or placing) the first semiconductor workpiece 11 within the central opening (e.g. through-hole opening) of the second semiconductor workpiece 15 (e.g. with the aid of the handling assembly 120, or a combination of both the handling assembly 120 and the alignment-detection assembly 130, of the system 100 in FIG. 1A, as previously described).

Specifically, with reference to FIG. 4A, initially, one primary face (e.g. a bottom surface) of the second semiconductor workpiece 15 may be laminated with a release layer (or release film) 453 (e.g. with the aid of the bonding assembly 140 of the system 100). According to various aspects, this release layer 453 may serve as a carrier film.

Next, as depicted in FIG. 4B, the first semiconductor workpiece 11 may be positioned within the central opening of the second semiconductor workpiece 15 having the laminated release layer 453, with one or more corner(s) of the first semiconductor workpiece 11 aligned with one or more corresponding corner(s) of the second semiconductor workpiece 15, using the “corner alignment” process, as previously described. In this manner, both the first semiconductor workpiece 11 and the second semiconductor workpiece 15 may be supported on the release layer 453.

Additionally, as depicted in FIG. 4C, the first semiconductor workpiece 11 and the second semiconductor workpiece 15, together with the release layer 453, may be disposed on a mounting stage 410—which may correspond to, or may be, the platform 113 of the workpiece-support assembly 110 or the first plate 142A of the bonding assembly 140.

Thereafter, with reference to FIG. 4D, adhesive (i.e. bonding material) in liquid form may be dispensed into the spaces or gaps between the first semiconductor workpiece 11 and the second semiconductor workpiece 15 (e.g. with the aid of the dispenser 148 of the bonding assembly 140). Specifically, according to various aspects, the dispenser 148 of the bonding assembly 140 may dispense liquid adhesive to fill the spaces or gaps defined between an outer side surface of the first semiconductor workpiece 11 and an inner side surface of the second semiconductor workpiece 15 that is facing the outer side surface of the first semiconductor workpiece 11. According to various aspects, this step may (e.g. optionally) involve flipping the first and the second semiconductor workpieces 11 and 15 (e.g. with the aid of a flipper or any suitable repositioning mechanism), if required.

Subsequently, with reference to FIG. 4E, the liquid adhesive may undergo curing until it solidifies. According to various aspects, the liquid adhesive may be cured via any of the following examples: thermal curing, ultraviolet curing, room-temperature curing, etc., (e.g. with the aid of the bonding assembly 140 of the system 100).

Finally, with reference to FIG. 4F, the first and the second semiconductor workpieces 11 and 15, which are bonded together with cured (i.e. solidified) adhesive 158, may be detached from the release layer 453 and the mounting stage 410.

According to various aspects, as an illustration, the bonded first and the second semiconductor workpieces 11 and 15 may then undergo a fiducial forming process (e.g. with the aid of the fiducial-marking assembly 160 of the system 100 of FIG. 1A, as earlier described) to form secondary alignment marker(s) (e.g. fiducials) 17 (as shown in FIG. 1J) on the second semiconductor workpiece 15 associated and/or aligned with secondary alignment marker(s) (e.g. fiducial hole(s)) 13 on the first semiconductor workpiece 11, before further undergoing a trimming process (e.g. with the aid of the trimming assembly 170 of the system 100 of FIG. 1A) to trim the edge(s) of the second semiconductor workpiece 15.

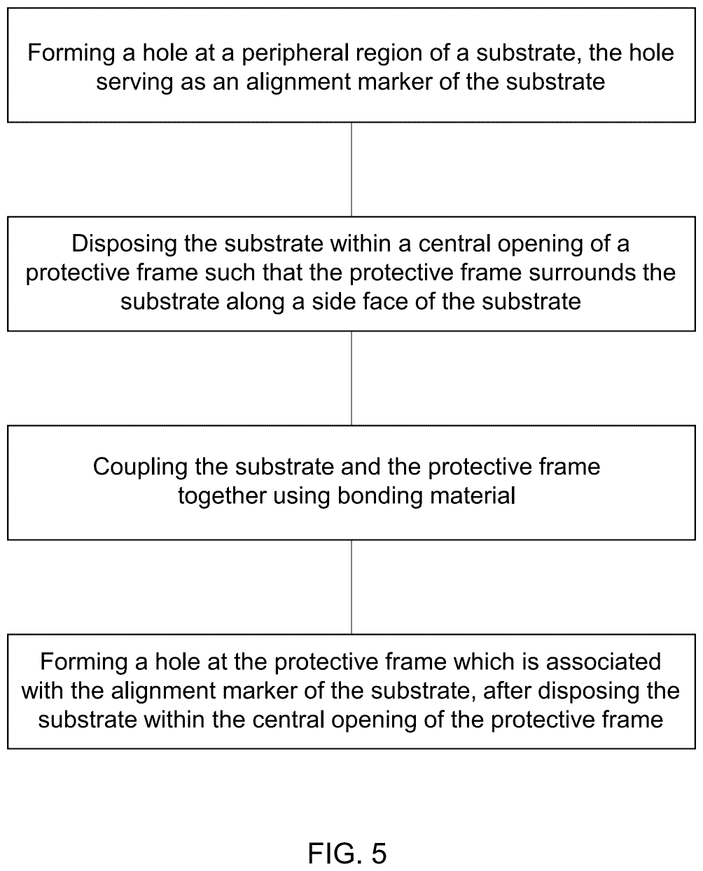

FIG. 5 depicts a method, according to various aspects.

According to various aspects, the method may include providing or forming at least one hole (also known as a “tooling hole”) at a peripheral region (e.g. a BE KOZ) of a substrate (e.g. corresponding to the first semiconductor workpiece 11). According to various aspects, the at least one hole may serve as at least one alignment marker (e.g. corresponding to at least one secondary alignment marker 13) of the substrate. According to various aspects, the peripheral region of the substrate may encompass the outer edges or perimeter of the substrate and may extend inward from the outer edges or perimeter of the substrate by a predetermined dimension. For example, this predetermined dimension (or an average thereof) may range between approximately 50 μm and approximately 20 mm (in other words, the range may include 50 μm and 20 mm), measured inward from the outer edges or perimeter of the substrate.

As an example, according to various aspects, each of the at least one hole may be, but is not limited to being, situated (e.g. provided or formed) at a respective corner region of the substrate.

According to various aspects, the substrate may include at least one via (e.g. through glass via) filled with conductive material, and each of the at least one hole at the peripheral region of the substrate may be larger (e.g. may have a diameter and/or opening that is larger) than that of each of the at least one via. As an example, according to various aspects, each of the at least one hole at the peripheral region of the substrate may have a diameter which falls within a range of between approximately 50 μm and approximately 5 mm.

According to various aspects, the method may include (e.g. further include), or may include subsequently, disposing (or placing) the substrate within a central opening of a protective frame (e.g. corresponding to the second semiconductor workpiece 15) such that the protective frame surrounds (e.g. entirely surrounds or encircles) the substrate along a side face (e.g. all outer side surfaces) of the substrate. As an example, the central opening of the protective frame may be a through-hole formed in a central or core region of the protective frame using any suitable process or mechanism, such as drilling or cutting (e.g. with the aid of a blade, tool bit, router bit, etc., which may be included in the system 100 of FIG. 1A, or may be provided in the trimming assembly 170 of the system 100).

According to various aspects, the method may include (e.g. further include), or may include subsequently, coupling the substrate and the protective frame together using bonding material (e.g. with the aid of the bonding assembly 140 of the system 100 of FIG. 1A).

As an example, according to various aspects, coupling the substrate and the protective frame together using bonding material may include (or involve) laminating a film of the bonding material (e.g. ABF, or dry film having similar properties as ABF, etc.) onto at least one primary face (e.g. upper and/or bottom surface) of both the substrate and the protective frame. For instance, with the substrate disposed within the central opening of the protective frame, a film of bonding material may be laminated onto the upper surfaces of the substrate and the protective frame, or a film of bonding material may be laminated onto the bottom surfaces of the substrate and the protective frame, or a first film of bonding material may be laminated onto the upper surfaces of the substrate and the protective frame while a second film of bonding material may be laminated onto the bottom surfaces of the substrate and the protective frame. According to various aspects, laminating the film of bonding material may involve the application of pressure and/or heat as well as involve curing (e.g. by any suitable curing process).

As another example, according to various aspects, coupling the substrate and the protective frame together using bonding material may include disposing (or dispensing) a liquid adhesive between an outer side face (e.g. all outer side surfaces) of the substrate and an inner side face (e.g. all inner side surfaces, defining and/or surrounding the central opening) of the protective frame (i.e. that is opposing or facing the side face of the substrate). In particular, the method may include filling (or substantively filling) the spaces or gaps between the side face of the substrate and the inner side face of the protective frame such that the liquid adhesive forms a continuous body of liquid that extends from (and/or connects) the outer side face of the substrate and the inner side face of the protective frame. Furthermore, this continuous body of liquid adhesive may have a height substantially equal to the thickness (or height) of the substrate and the protective frame. Thereafter, the method may include curing the liquid adhesive (e.g. via any suitable process or mechanism) until the adhesive hardens (or solidifies).

According to various aspects, the method may include (e.g. further include) disposing the substrate and the protective frame onto a release layer (or carrier film), or applying a release layer thereon, prior to coupling the substrate and the protective frame together with the bonding material. According to various aspects, the release layer (or carrier film) may possess a property that enables it to be detachable from the substrate, the protective frame, as well as the bonding material (e.g. even if the bonding material is cured while in contact with the release layer).

According to various aspects, the method may include (e.g. further include) forming at least one hole at the protective frame which is associated and/or aligned with the alignment marker of the substrate, after disposing the substrate within the central opening of the protective frame and/or after coupling the substrate and the protective frame together using bonding material. According to various aspects, this at least one hole on the protective frame may serve as at least one secondary alignment marker of the protective frame.

According to various aspects, the method may include (e.g. further include), or may include subsequently, trimming (or removing) material from the protective frame (e.g. at its outer edges or peripheral region), based on the at least one hole of the protective frame (i.e. serving as at least one secondary alignment marker of the protective frame) (e.g. with the aid of the trimming assembly 170, or a combination of both the trimming assembly 170 and the alignment-detection assembly 130, of the system 100 of FIG. 1A).

According to various aspects, the method may include (e.g. further include) filling the at least one hole of the substrate with material, after forming the at least one hole at the protective frame and/or after trimming the protective frame. According to various aspects, this material may serve as a “plug” in the at least one hole of the substrate. As some non-limiting examples, the material used as the “plug” may include or may be a polymer, a non-magnetic material (or a magnetic material), a curable material (e.g. capable of transitioning from a liquid to a solid state through a curing process), a mold or molding material, a heat-resistant material, a dielectric material, and/or an insulating (e.g. electrically insulating) material, etc. As a specific example, the material may correspond to (e.g. may be similar or identical to), or may be, the bonding material or build-up layer(s) (e.g. polymer, ABF resin, etc.).

Various aspects have thus described a system and method which represent a significant advancement in semiconductor manufacturing technology. By combining the benefits of glass substrates with the mechanical support of protective CCL frames, the present disclosure overcomes challenges posed by brittle materials, such as glass, while simultaneously enhancing the efficiency and reliability of semiconductor assembly processes.

Through the integration of automation technologies, the system empowers industry stakeholders to meet the evolving demands of the industry, while maintaining high levels of precision, efficiency, and quality in their production processes. Consequently, this advancement has the potential to drive progress in semiconductor technology.

While the disclosure has been particularly shown and described with reference to specific aspects, it should be understood by those skilled in the art that various changes, modification, and variation in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

To more readily understand and put into practical effect the present cleaning assembly, cleaning system, and method, they will now be described by way of examples. For the sake of brevity, duplicate descriptions of features and properties may be omitted.

### Examples

Example 1 provides a system. The system may include a workpiece-support assembly. The system may further include an alignment-detection assembly. The alignment-detection assembly may be configured to detect a primary alignment marker and a secondary alignment marker of a first semiconductor workpiece and a primary alignment marker of a second semiconductor workpiece (e.g. which may be disposed on the workpiece-support assembly). The system may further include a handling assembly configured to be movable relative to the workpiece-support assembly based on the detection (i.e. by the alignment-detection assembly) of the primary alignment marker of the first semiconductor workpiece and the primary alignment marker of the second semiconductor workpiece. The system may further include a bonding assembly configured to dispense bonding material based on the detection of the primary alignment marker of the first semiconductor workpiece and the primary alignment marker of the second semiconductor workpiece. The system may further include a fiducial-marking assembly configured to be actuable (or configured to actuate) based on the detection of the secondary alignment marker of the first semiconductor workpiece.

Example 2 may include the system of example 1 and/or any other example disclosed herein, for which, the workpiece-support assembly may be configured to receive the first semiconductor workpiece and the second semiconductor workpiece, and may be further configured to convey each of the first semiconductor workpiece and the second semiconductor workpiece along at least a portion or length of the workpiece-support assembly.

Example 3 may include the system of example 1 and/or any other example disclosed herein, for which, the first semiconductor workpiece may include or may be a substrate, while the second semiconductor workpiece may include or may be a protective frame with (e.g. having and/or defining) a central opening, and the handling assembly may be configured to dispose the first semiconductor workpiece within the central opening of the second semiconductor workpiece, with the primary alignment marker of the first semiconductor workpiece aligned with the primary alignment marker of the second semiconductor workpiece.

Example 4 may include the system of example 1 and/or any other example disclosed herein, for which, the alignment-detection assembly may include an optical sensor.

Example 5 may include the system of example 1 and/or any other example disclosed herein, for which, the alignment-detection assembly may be configured to identify a corner region of the first semiconductor workpiece as the primary alignment marker of the first semiconductor workpiece and to identify a corner region of the second semiconductor workpiece as the primary alignment marker of the second semiconductor workpiece.

Example 6 may include the system of example 1 and/or any other example disclosed herein, for which, the bonding assembly may include a workpiece-holding portion configured to accommodate the first semiconductor workpiece and the second semiconductor workpiece, a first plate, and a second plate, for which, the first plate and the second plate may be configured to be movable relative to each other along a movement axis extending across the workpiece-holding portion, and the bonding assembly may be in fluidic communication with a mold cavity defined by the first plate and the second plate (e.g. to dispense bonding material into the mold cavity).

Example 7 may include the system of example 1 and/or any other example disclosed herein, for which, the bonding assembly may be configured to dispense the bonding material as a continuous film of the bonding material.

Example 8 may include the system of example 1 and/or any other example disclosed herein, for which, the bonding material may include or may be a dielectric material and/or an insulating material and/or an adhesive.

Example 9 may include the system of example 1 and/or any other example disclosed herein, for which, the fiducial-marking assembly may be configured to form a hole on the second semiconductor workpiece, for which the hole may serve as a secondary alignment marker of the second semiconductor workpiece that is associated with the secondary alignment marker of the first semiconductor workpiece.

Example 10 may include the system of example 9 and/or any other example disclosed herein, for which, the system may further include a trimming assembly configured to remove (e.g. trim) material from the second semiconductor workpiece based on the secondary alignment marker of the second semiconductor workpiece.

Example 11 provides a system. The system may include a workpiece-support assembly which may include a platform. The system may further include an alignment-detection assembly which may include an optical sensor oriented towards the platform. The system may further include a handling assembly which may include at least one manipulator positioned along at least a first movement plane that is substantially parallel with the platform and/or at least a second movement plane that is substantially perpendicular to the platform. The system may further include a bonding assembly which may include a dispenser positioned over the platform. The system may further include a fiducial-marking assembly which may include a drill that is oriented towards the platform. The controller of the system may be electrically connected (e.g. wired or wirelessly) to each of the optical sensor, the at least one manipulator, the dispenser, and the drill.

Example 12 may include the system of example 11 and/or any other example disclosed herein, for which, the workpiece-support assembly may further include a first workpiece-loading bay and a second workpiece-loading bay and, for which, the workpiece-support assembly may further include a conveyor extending between the platform and each of the first workpiece-loading bay and the second workpiece-loading bay.

Example 13 may include the system of example 11 and/or any other example disclosed herein, for which, the bonding assembly may include or may be a compression molding unit, the compression molding unit including a workpiece-holding portion, a first plate, and a second plate, for which the first plate and the second plate may be movable relative to each other along a movement axis extending across the workpiece-holding portion, and the dispenser of the bonding assembly may be in fluidic communication with a mold cavity defined by the first plate and the second plate, to dispense bonding material into the mold cavity.

Example 14 may include the system of example 11 and/or any other example disclosed herein, for which, the dispenser of the bonding assembly may include or may be a film-dispensing unit that dispenses a bonding material as a continuous film of the bonding material.

Example 15 may include the system of example 11 and/or any other example disclosed herein, for which, the dispenser dispenses a bonding material that may include or may be a dielectric material and/or an insulating material and/or an adhesive.

Example 16 may include the system of example 11 and/or any other example disclosed herein, for which, the drill of the fiducial-marking assembly may be a laser drill or a mechanical drill.

Example 17 may include the system of example 11 and/or any other example disclosed herein, for which, the system may further include a trimming assembly which may include a cutter that is oriented towards the platform.

Example 18 provides a system. The system may include a workpiece-support assembly or module to support or for supporting a substrate and a protective frame. The system may further include an alignment-detection assembly or module configured to detect a primary alignment marker and a secondary alignment marker of the substrate and a primary alignment marker of the protective frame. The system may further include a handling assembly or module configured to place the substrate within a central opening of the protective frame, with the primary alignment marker of the substrate aligned with the primary alignment marker of the protective frame (e.g. based on the detection by the alignment-detection assembly or module). The system may further include a bonding assembly or module configured to dispense bonding material to bond or for bonding the substrate to the protective frame, with the substrate within the central opening of the protective frame. The system may further include a fiducial-marking assembly or module configured to form a hole on the protective frame, with the hole being associated (e.g. aligned) with the secondary alignment marker of the substrate.

Example 19 may include the system of example 18 and/or any other example disclosed herein, for which, the alignment-detection assembly or module may be configured to identify and detect the hole on or at the protective frame as a secondary alignment marker of the protective frame, and the system may further include a trimming assembly or module configured to remove material from the protective frame based on the detection (i.e. by the alignment-detection assembly or module) of the secondary alignment marker of the protective frame.

Example 20 may include the system of example 18 and/or any other example disclosed herein, for which, the alignment-detection assembly may be configured to identify a corner region of the substrate as the primary alignment marker of the substrate and identify a corner region of the protective frame as the primary alignment marker of the protective frame.

Example 21 may include the system of example 18 and/or any other example disclosed herein, for which, the system may further include a controller electrically connected to at least the handling assembly or module and the bonding assembly or module and, for which, the controller may be configured to control the bonding assembly or module to dispense the bonding material upon completion of the placement of the substrate within the central opening of the protective frame by the handling assembly or module.

Example 22 may include the system of example 18 and/or any other example disclosed herein, for which, the system may further include a controller electrically connected to at least the bonding assembly or module and the fiducial-marking assembly or module and, for which, the controller may be configured to control the fiducial-marking assembly or module to form the hole on the protective frame upon completion of the dispensing of the bonding material by the bonding assembly or module.

Example 23 provides a system. The system may include a workpiece-support assembly or module which may include a platform to support a substrate and a protective frame. The system may further include an alignment-detection assembly or module which may include a sensor configured to detect a primary alignment marker and a secondary alignment marker of the substrate and a primary alignment marker of the protective frame. The system may further include a handling assembly or module which may include at least one manipulator configured to place the substrate within a central opening of the protective frame, with the primary alignment marker of the substrate aligned with the primary alignment marker of the protective frame (e.g. based on the detection by the alignment-detection assembly or module). The system may further include a bonding assembly or module which may include a dispenser configured to dispense bonding material to bond the substrate to the protective frame, with the substrate within the central opening of the protective frame. The system may further include a fiducial-marking assembly or module which may include a drill configured to form a hole on the protective frame that is aligned with the secondary alignment marker of the substrate.

Example 24 may include the system of example 23 and/or any other example disclosed herein, for which, the sensor of the alignment-detection assembly or module may be configured to identify and detect the hole on the protective frame as a secondary alignment marker of the protective frame, and the system may further include a trimming assembly or module which may include a cutter configured to remove material from the protective frame based on the detection by the alignment-detection assembly or module of the secondary alignment marker of the protective frame.

Example 25 may include the system of example 23 and/or any other example disclosed herein, for which, the sensor of the alignment-detection assembly may be configured to identify a corner region of the substrate as the primary alignment marker of the substrate and identify a corner region of the protective frame as the primary alignment marker of the protective frame.

Example 26 may include the system of example 23 and/or any other example disclosed herein, for which, the system may further include a controller electrically connected to at least the at least one manipulator and the dispenser and, for which, the controller controls the dispenser to dispense the bonding material upon completion of the placement of the substrate within the central opening of the protective frame by the at least one manipulator.

Example 27 may include the system of example 23 and/or any other example disclosed herein, for which, the system may further include a controller electrically connected to at least the dispenser and the drill and, for which, the controller controls the drill to form the hole on the protective frame upon completion of the dispensing of the bonding material by the dispenser.

As an illustration, any of the aforementioned “module” may refer to a sub-system of the system. As another illustration, any of the aforementioned “module” may refer to a housing or casing that may house or encase one or more components. As another illustration, any of the aforementioned “module” may refer to an arrangement (or assembly) of component(s). As yet another illustration, any of the aforementioned “module” may refer to any equipment (e.g. tool, device, etc.) capable of (or configured) to perform its intended function.

Example 28 provides a method. The method may include forming a hole at a peripheral region of a substrate, the hole serving as an alignment marker of the substrate. The method may further include disposing the substrate within a central opening of a protective frame such that the protective frame surrounds the substrate along a side face of the substrate. The method may further include coupling the substrate and the protective frame together using bonding material. The method may further include forming a hole at the protective frame which is associated with the alignment marker of the substrate, after disposing the substrate within the central opening of the protective frame.

Example 29 may include the method of example 28 and/or any other example disclosed herein, for which, the hole at the protective frame may be formed after coupling the substrate and the protective frame together using bonding material.

Example 30 may include the method of example 28 and/or any other example disclosed herein, for which, the substrate may include at least one via filled with conductive material, and the hole of the substrate serving as the alignment marker of the substrate may have a size (e.g. diameter) that is larger than that of the via.

Example 31 may include the method of example 28 and/or any other example disclosed herein, for which, the hole of the substrate serving as the alignment marker of the substrate may be formed at a corner region of the substrate.

Example 32 may include the method of example 28 and/or any other example disclosed herein, for which, coupling the substrate and the protective frame together using bonding material may involve laminating a film of the bonding material onto the substrate and the protective frame.

Example 33 may include the method of example 28 and/or any other example disclosed herein, for which, coupling the substrate and the protective frame together using bonding material may involve disposing a liquid adhesive between the side face of the substrate and an inner side face of the protective frame that is facing the side face of the substrate, and thereafter, curing the liquid adhesive until it solidifies.

Example 34 may include the method of example 28 and/or any other example disclosed herein, for which, the method may further include filling the hole of the substrate with material after forming the hole at the protective frame.

Example 35 provides a non-transitory computer-readable medium which includes instructions which, when (or if) executed by a processor, make the processor (or cause the processor to) initiate and/or perform formation of a hole at a peripheral region of a substrate, the hole serving as an alignment marker of the substrate, disposing of the substrate within a central opening of a protective frame such that the protective frame surrounds the substrate along a side face of the substrate, coupling of the substrate and the protective frame together using bonding material, and formation of a hole at the protective frame which is associated with the alignment marker of the substrate, after disposing the substrate within the central opening of the protective frame.

Example 36 may include the non-transitory computer-readable medium of example 35 and/or any other example disclosed herein, for which, the hole at the protective frame may be formed after coupling the substrate and the protective frame together using bonding material.

Example 37 may include the non-transitory computer-readable medium of example 35 and/or any other example disclosed herein, for which, the substrate may include at least one via filled with conductive material, and the hole of the substrate serving as the alignment marker of the substrate may have a size (e.g. diameter) that is larger than that of the via.

Example 38 may include the non-transitory computer-readable medium of example 35 and/or any other example disclosed herein, for which, the hole of the substrate serving as the alignment marker of the substrate may be formed at a corner region of the substrate.

Example 39 may include the non-transitory computer-readable medium of example 35 and/or any other example disclosed herein, for which, coupling the substrate and the protective frame together using bonding material may involve laminating a film of the bonding material onto the substrate and the protective frame.

Example 40 may include the non-transitory computer-readable medium of example 35 and/or any other example disclosed herein, for which, coupling the substrate and the protective frame together using bonding material may involve disposing a liquid adhesive between the side face of the substrate and an inner side face of the protective frame that is facing the side face of the substrate, and thereafter, curing the liquid adhesive until it solidifies.

Example 41 may include the non-transitory computer-readable medium of example 35 and/or any other example disclosed herein, for which, the processor may further perform filling the hole of the substrate with material after forming the hole at the protective frame.

Example 42 provides a non-transitory computer-readable medium which includes instructions which, when (or if) executed by a processor, make the processor (or cause the processor to) cause a sensor of an alignment-detection assembly of a system to detect a primary alignment marker and a secondary alignment marker of a first semiconductor workpiece and a primary alignment marker of a second semiconductor workpiece, disposed on a platform of a workpiece-support assembly of the system, cause at least one manipulator of a handling assembly of the system to move relative to the platform based on the detection of the primary alignment marker of the first semiconductor workpiece and the primary alignment marker of the second semiconductor workpiece, cause a dispenser of a bonding assembly of the system to dispense bonding material based on the detection of the primary alignment marker of the first semiconductor workpiece and the primary alignment marker of the second semiconductor workpiece, and cause a drill of a fiducial-marking assembly of the system to actuate based on the detection of the secondary alignment marker of the first semiconductor workpiece.

Example 43 provides a non-transitory computer-readable medium which includes instructions which, when (or if) executed by a processor, make the processor (or cause the processor to) cause a sensor of an alignment-detection assembly or module of a system to detect a primary alignment marker and a secondary alignment marker of a substrate and a primary alignment marker of a protective frame, cause at least one manipulator of a handling assembly or module of the system to place the substrate within a central opening of the protective frame, with the primary alignment marker of the substrate aligned with the primary alignment marker of the protective frame, based on the detection by the alignment-detection assembly or module (e.g. of the primary alignment marker of the substrate and the primary alignment marker of the protective frame), cause a dispenser of a bonding assembly or module of the system to dispense bonding material to bond the substrate to the protective frame, with the substrate within the central opening of the protective frame, and cause a drill of a fiducial-marking assembly or module of the system to form a hole on the protective frame that is aligned with the secondary alignment marker of the substrate.

In a further example, any one or more of examples 1 to 43 may be combined.

1. A system comprising:
a workpiece-support assembly comprising a platform;
an alignment-detection assembly comprising an optical sensor oriented towards the platform;
a handling assembly comprising at least one manipulator positioned along at least a first movement plane that is substantially parallel with the platform or at least a second movement plane that is substantially perpendicular to the platform;
a bonding assembly comprising a dispenser positioned over the platform;
a fiducial-marking assembly comprising a drill that is oriented towards the platform; and
a controller electrically connected to each of the optical sensor, the at least one manipulator, the dispenser, and the drill.

2. The system of claim 1,
wherein the workpiece-support assembly further comprises a first workpiece-loading bay and a second workpiece-loading bay; and
wherein the workpiece-support assembly further comprises a conveyor extending between the platform and each of the first workpiece-loading bay and the second workpiece-loading bay.

3. The system of claim 1,
wherein the bonding assembly comprises a compression molding unit, the compression molding unit comprising:
a workpiece-holding portion,
a first plate, and
a second plate,
wherein the first plate and the second plate are movable relative to each other along a movement axis extending across the workpiece-holding portion, and
wherein the dispenser of the bonding assembly is in fluidic communication with a mold cavity defined by the first plate and the second plate, to dispense bonding material into the mold cavity.

4. The system of claim 1,
wherein the dispenser of the bonding assembly comprises a film-dispensing unit that dispenses a bonding material as a continuous film of the bonding material.

5. The system of claim 1,
wherein the dispenser dispenses a bonding material, the bonding material comprising a dielectric material or an insulating material.

6. The system of claim 1,
wherein the dispenser dispenses a bonding material, the bonding material comprising an adhesive.

7. The system of claim 1,
wherein the drill of the fiducial-marking assembly is a laser drill or a mechanical drill.

8. The system of claim 1, further comprising:
a trimming assembly comprising a cutter that is oriented towards the platform.

9. A system comprising:
a workpiece-support assembly comprising a platform to support a substrate and a protective frame;
an alignment-detection assembly comprising a sensor configured to detect a primary alignment marker and a secondary alignment marker of the substrate and a primary alignment marker of the protective frame;
a handling assembly comprising at least one manipulator configured to place the substrate within a central opening of the protective frame, with the primary alignment marker of the substrate aligned with the primary alignment marker of the protective frame;
a bonding assembly comprising a dispenser configured to dispense bonding material to bond the substrate to the protective frame, with the substrate within the central opening of the protective frame; and
a fiducial-marking assembly comprising a drill configured to form a hole on the protective frame that is aligned with the secondary alignment marker of the substrate.

10. The system of claim 9,
wherein the sensor of the alignment-detection assembly is configured to identify and detect the hole on the protective frame as a secondary alignment marker of the protective frame;
wherein the system further comprises:
a trimming assembly comprising a cutter configured to remove material from the protective frame based on the detection by the alignment-detection assembly of the secondary alignment marker of the protective frame.

11. The system of claim 9,
wherein the sensor of the alignment-detection assembly is configured to
identify a corner region of the substrate as the primary alignment marker of the substrate, and
identify a corner region of the protective frame as the primary alignment marker of the protective frame.

12. The system of claim 9, further comprising:
a controller electrically connected to at least the at least one manipulator and the dispenser;
wherein the controller controls the dispenser to dispense the bonding material upon completion of the placement of the substrate within the central opening of the protective frame by the at least one manipulator.

13. The system of claim 9, further comprising:
a controller electrically connected to at least the dispenser and the drill;
wherein the controller controls the drill to form the hole on the protective frame upon completion of the dispensing of the bonding material by the dispenser.

14. A method comprising:
forming a hole at a peripheral region of a substrate, the hole serving as an alignment marker of the substrate;
disposing the substrate within a central opening of a protective frame such that the protective frame surrounds the substrate along a side face of the substrate;
coupling the substrate and the protective frame together using bonding material; and
forming a hole at the protective frame which is associated with the alignment marker of the substrate, after disposing the substrate within the central opening of the protective frame.

15. The method of claim 14,
wherein the hole at the protective frame is formed after coupling the substrate and the protective frame together using bonding material.

16. The method of claim 14,
wherein the substrate comprises at least one via filled with conductive material; and
wherein the hole of the substrate serving as the alignment marker of the substrate has a diameter that is larger than that of the at least one via.

17. The method of claim 14,
wherein the hole of the substrate serving as the alignment marker of the substrate is formed at a corner region of the substrate.

18. The method of claim 14,
wherein coupling the substrate and the protective frame together using bonding material comprises laminating a film of the bonding material onto the substrate and the protective frame.

19. The method of claim 14,
wherein coupling the substrate and the protective frame together using bonding material comprises:
disposing a liquid adhesive between the side face of the substrate and an inner side face of the protective frame that is facing the side face of the substrate, and thereafter,
curing the liquid adhesive until it solidifies.

20. The method of claim 14, further comprising:
filling the hole of the substrate with material after forming the hole at the protective frame.
